(19) United States
(12) Patent Application Publication
(10) Pub. No.: US 2026/0239920 A1
(43) Pub. Date: Aug. 13, 2026

(54) SUBSTRATE BONDING APPARATUS AND SUBSTRATE BONDING METHOD

(71) Applicant: SCREEN Holdings Co., Ltd., Kyoto (JP)

(72) Inventors: Koji HASHIMOTO, Kyoto-shi, Kyoto (JP); Hideki SHIMIZU, Kyoto-shi, Kyoto (JP); Koji ODA, Kyoto-shi, Kyoto (JP)

(21) Appl. No.: 19/160,308

(22) PCT Filed: Nov. 13, 2023
(86) PCT No.: PCT/JP2023/040744

§ 371 Date: Aug. 27, 2025

(30) Foreign Application Priority Data
Mar. 23, 2023 (JP) 2023-047374
Mar. 23, 2023 (JP) 2023-047375
Mar. 23, 2023 (JP) 2023-047376

(51) Int. Cl. H10P 72/50; H10P 72/00

(52) U.S. Cl. CPC H10P 72/53; H10P 72/0438

(57) ABSTRACT

A substrate bonding apparatus includes a controller that performs alignment adjustment between a first substrate held by a first chuck and a second substrate held by a second chuck by relatively moving the first chuck and the second chuck by an actuator mechanism based on an image of a first alignment mark generated by a first camera. When it is determined that an inclination angle of the first alignment mark with respect to a longitudinal direction or a lateral direction of the image generated by the first camera exceeds a first upper limit value, the controller causes a first rotation motor to rotate the first substrate and the first chuck such that the inclination angle of the first alignment mark decreases to the first upper limit value or less, and then causes the first camera to photograph the first alignment mark.

### CROSS-REFERENCE TO RELATED APPLICATIONS

This application is the U.S. National Phase under 35 U.S.C. 371 of International Application No. PCT/JP2023/040744, filed on Nov. 13, 2023, which claims the benefit of priority to Japanese Patent Application No. 2023-047374, Japanese Patent Application No. 2023-047375 and Japanese Patent Application No. 2023-047376 filed on Mar. 23, 2023, the entire contents of which are hereby incorporated herein by reference.

### BACKGROUND OF THE INVENTION

### 1. Field of the Invention

The present invention relates to a substrate bonding apparatus and a substrate bonding method that bond two substrates. The substrate includes a semiconductor wafer, a substrate for a FPD (Flat Panel Display) such as a liquid crystal display and an organic EL (electroluminescence) display, a substrate for an optical disc, a substrate for a magnetic disc, a substrate for a magneto-optical disc, a substrate for a photomask, a ceramic substrate, a substrate for a solar cell, and the like, for example.

### 2. Description of the Related Art

Patent Literature 1 discloses a normal-temperature bonding apparatus that bonds two wafers together. This normal-temperature bonding apparatus includes: a positioning stage carriage that holds one wafer; an electrostatic chuck that holds one wafer above the positioning stage carriage; a lighting device that emits infrared rays toward a hole vertically penetrating the positioning stage carriage and a hole vertically penetrating the electrostatic chuck; and a camera that photographs an alignment mark of two wafers to be bonded to each other on the basis of the infrared rays having passed through the hole of the positioning stage carriage and the hole of the electrostatic chuck through the two wafers to be bonded to each other.

### CITATION LIST

Patent Literature
Patent Literature 1: JP 2013-51358 A

### SUMMARY OF INVENTION

### Technical Problem

Preferred embodiments of the present invention provide a substrate bonding apparatus and a substrate bonding method capable of performing alignment adjustment between two substrates with higher accuracy.

### Solution to Problem

A preferred embodiment of the present invention provides a substrate bonding apparatus including: a first chuck that holds a first substrate; a second chuck that holds a second substrate; a first camera that photographs a first alignment mark of the first substrate held by the first chuck; an actuator mechanism that relatively moves the first chuck and the second chuck while the first substrate is held by the first chuck and the second substrate is held by the second chuck; and a controller that performs alignment adjustment between the first substrate held by the first chuck and the second substrate held by the second chuck by relatively moving the first chuck and the second chuck by the actuator mechanism based on an image of the first alignment mark generated by the first camera, and then bonds the first substrate held by the first chuck and the second substrate held by the second chuck by relatively moving the first chuck and the second chuck by the actuator mechanism, wherein the actuator mechanism includes a first rotation motor that rotates the first substrate and the first chuck around a center line of the first chuck while the first substrate is held by the first chuck, and when the first alignment mark has a shape capable of specifying a height direction and a width direction orthogonal to each other, the controller determines whether or not an inclination angle of the first alignment mark with respect to a longitudinal direction or a lateral direction of an image generated by the first camera exceeds a first upper limit value, and when it is determined that the inclination angle of the first alignment mark exceeds the first upper limit value, the controller causes the first rotation motor to rotate the first substrate and the first chuck such that the inclination angle of the first alignment mark decreases to the first upper limit value or less, and then causes the first camera to photograph the first alignment mark.

In the embodiment, at least one of the following features may be added to the substrate bonding apparatus.

The substrate bonding apparatus further includes: a second camera that photographs a second alignment mark of the second substrate held by the second chuck, wherein the controller performs the alignment adjustment by relatively moving the first chuck and the second chuck by the actuator mechanism based on the image of the first alignment mark generated by the first camera and the image of the second alignment mark generated by the second camera, the actuator mechanism further includes a second rotation motor that rotates the second substrate and the second chuck around a center line of the second chuck while the second substrate is held by the second chuck, and when the second alignment mark has a shape capable of specifying a height direction and a width direction orthogonal to each other, the controller determines whether or not an inclination angle of the second alignment mark with respect to a longitudinal direction or a lateral direction of an image generated by the second camera exceeds a second upper limit value, and when it is determined that the inclination angle of the second alignment mark exceeds the second upper limit value, the controller causes the second rotation motor to rotate the second substrate and the second chuck such that the inclination angle of the second alignment mark decreases to the second upper limit value or less, and then causes the second camera to photograph the second alignment mark.

Another preferred embodiment of the present invention provides a substrate bonding method including: holding a first substrate by a first chuck wherein a first alignment mark having a shape capable of specifying a height direction and a width direction orthogonal to each other is formed on the first substrate; holding a second substrate by a second chuck; photographing the first alignment mark with a first camera and generating an image; determining whether or not an inclination angle of the first alignment mark with respect to a longitudinal direction or a lateral direction of the generated image exceeds a first upper limit value; rotating the first substrate and the first chuck such that the inclination angle of the first alignment mark decreases to the first upper limit value or less while the first substrate is held by the first chuck when it is determined that the inclination angle of the first alignment mark exceeds the first upper limit value; photographing the first alignment mark with the first camera after rotating the first substrate and the first chuck; performing alignment adjustment between the first substrate held by the first chuck and the second substrate held by the second chuck by relatively moving the first chuck and the second chuck based on an image of the first alignment mark generated by the first camera after rotating the first substrate and the first chuck; and bonding the first substrate held by the first chuck and the second substrate held by the second chuck by relatively moving the first chuck and the second chuck. At least one of the above-mentioned features of the substrate bonding apparatus may be added to the substrate bonding method.

Still another preferred embodiment of the present invention provides a substrate bonding apparatus including: a first chuck that holds a first substrate; a second chuck that holds a second substrate; an actuator mechanism that bonds the first substrate held by the first chuck and the second substrate held by the second chuck by relatively moving the first chuck and the second chuck; a first fixing reference that includes a first reference mark serving as an indirect reference when aligning the first substrate held by the first chuck and a transparent first display plate on which the first reference mark is marked and that transmits visible light, the first fixing reference being provided at a position not overlapping the first substrate held by the first chuck when viewed in a direction along a center line of the first chuck, the first fixing reference moving together with the first chuck; a second fixing reference that includes a second reference mark serving as an indirect reference when aligning the second substrate held by the second chuck and a second display plate on which the second reference mark is marked, the second fixing reference being provided at a position not overlapping the second substrate held by the second chuck when viewed in a direction along a center line of the second chuck, the second fixing reference moving together with the second chuck; an alignment camera that is a visible light camera for photographing the first reference mark and the second reference mark by photographing the second fixed reference through the first fixed reference; and a controller that performs alignment adjustment between the first substrate held by the first chuck and the second substrate held by the second chuck by relatively moving the first chuck and the second chuck by the actuator mechanism while causing the alignment camera to photograph the first reference mark and the second reference mark.

In the embodiment, at least one of the following features may be added to the substrate bonding apparatus.

The substrate bonding apparatus further includes: a first camera that photographs a first alignment mark of the first substrate held by the first chuck and the first reference mark; and a second camera that photographs a second alignment mark of the second substrate held by the second chuck and the second reference mark.

At least a portion of the period in which the first camera photographs the first alignment mark of the first substrate while the first substrate is held by the first chuck may be or may not be the same as the period in which the first camera photographs the first reference mark. When the first alignment mark is photographed before the first substrate is held by the first chuck, the first alignment mark may not be photographed while the first substrate is held by the first chuck. That is, when the first substrate is held by the first chuck while the position and angle of the first substrate are grasped in advance, the first alignment mark may not be photographed. The same applies to the second camera.

Still another preferred embodiment of the present invention provides a substrate bonding apparatus including: a first chuck that is stationary in a horizontal direction and holds a first substrate; a second chuck that is movable in the horizontal direction and holds a second substrate; an actuator mechanism that moves the second chuck in the horizontal direction; and a lattice interference type displacement detector that detects displacement of the second chuck in an X direction and a Y direction which are horizontal directions orthogonal to each other.

In the embodiment, at least one of the following features may be added to the substrate bonding apparatus.

The displacement detector includes a scale that moves in the X direction and the Y direction together with the second chuck, and a detection head that detects displacement of the scale in the X direction and the Y direction in a non-contact manner with the scale.

The scale overlaps the second chuck in a plan view of the second chuck, and the detection head overlaps the scale in a plan view of the second chuck.

The substrate bonding apparatus further includes: a base member that has a principal surface extending along the horizontal direction; a support portion that is fixed to the base member and supports the first chuck; and a linear guide that is fixed on the principal surface of the base member, wherein the actuator mechanism includes a horizontal actuator that moves the second chuck along the linear guide, and the detection head is fixed to the base member.

The substrate bonding apparatus further includes: a first imaging portion that moves in the X direction and the Y direction together with the second chuck and images the first substrate; and a second imaging portion that is fixed in the horizontal direction and images the second substrate, wherein alignment of the first substrate and the second substrate in the horizontal direction is performed based on a first image acquired by the first imaging portion, a second image acquired by the second imaging portion, and a value indicated by the displacement detector.

The above and other objects, features, and advantages of the present invention will become more apparent from the following detailed description of the embodiments with reference to the attached drawings.

### BRIEF DESCRIPTION OF THE DRAWINGS

FIG. 1 is a schematic plan view of a substrate bonding apparatus according to the first embodiment of the present invention.

FIG. 2 is a process diagram for illustrating one example of a substrate bonding method performed by the substrate bonding apparatus.

FIG. 3 is a schematic view showing one example of cross-sections of a first substrate and a second substrate before and after being bonded.

FIG. 4 is a schematic plan view of the first substrate for illustrating a first alignment mark of the first substrate.

FIG. 5 is a schematic plan view of the second substrate for illustrating a second alignment mark of the second substrate.

FIG. 6 is a schematic view showing the first alignment mark and the second alignment mark before and after alignment adjustment of the first substrate and the second substrate.

FIG. 7 is a perspective view of a bonding unit.

FIG. 8 is a plan view of the bonding unit.

FIG. 9 is a view of the bonding unit as viewed horizontally in a Y direction.

FIG. 10A is a schematic plan view of a first chuck.

FIG. 10B is a schematic plan view of the first chuck.

FIG. 11 is a view of a first bonding module as viewed horizontally in an X direction.

FIG. 12 is a plan view of the first bonding module.

FIG. 13 is a plan view of a first stage.

FIG. 14 is a view of the first stage as viewed horizontally in a direction of an arrow XIV shown in FIG. 13.

FIG. 15 is a view of a second bonding module as viewed horizontally in the X direction.

FIG. 16 is an enlarged view of a portion of FIG. 16.

FIG. 17 is a plan view of the second bonding module.

FIG. 18 is a view of the second bonding module as viewed horizontally in the Y direction.

FIG. 19 is a plan view of a second stage.

FIG. 20 is a view of the second stage as viewed horizontally in a direction of an arrow XX shown in FIG. 19.

FIG. 21 is a plan view of the bonding unit.

FIG. 22 is a view of a second camera horizontally viewed in the Y direction, the second camera photographing the second substrate.

FIG. 23 is a view of a first camera horizontally viewed in the Y direction, the first camera photographing the first substrate.

FIG. 24 is a view of an alignment camera that is photographing a first fixed reference and a second fixed reference as viewed horizontally in the Y direction.

FIG. 25 is a view of the alignment camera viewed horizontally in a direction of an arrow XXV shown in FIG. 24.

FIG. 26 is a schematic view showing one example of an image of a cross-shaped first alignment mark generated by the first camera.

FIG. 27 is a block diagram of a displacement detector.

FIG. 28 is a view showing a vertical cross-section of the displacement detector.

FIG. 29 is a view of the displacement detector viewed horizontally in a direction of an arrow XXIX shown in FIG. 28.

FIG. 30 is a block diagram showing an electrical arrangement of the substrate bonding apparatus.

FIG. 31A is a schematic view for illustrating a first example of bonding of the first substrate and the second substrate performed by the bonding unit.

FIG. 31B is a schematic view for illustrating the first example of bonding of the first substrate and the second substrate performed by the bonding unit.

FIG. 31C is a schematic view for illustrating the first example of bonding of the first substrate and the second substrate performed by the bonding unit.

FIG. 31D is a schematic view for illustrating the first example of bonding of the first substrate and the second substrate performed by the bonding unit.

FIG. 31E is a schematic view for illustrating the first example of bonding of the first substrate and the second substrate performed by the bonding unit.

FIG. 31F is a schematic view for illustrating the first example of bonding of the first substrate and the second substrate performed by the bonding unit.

FIG. 31G is a schematic view for illustrating the first example of bonding of the first substrate and the second substrate performed by the bonding unit.

FIG. 31H is a schematic view for illustrating the first example of bonding of the first substrate and the second substrate performed by the bonding unit.

FIG. 32A is a schematic view for illustrating a second example of bonding of the first substrate and the second substrate performed by the bonding unit.

FIG. 32B is a schematic view for illustrating the second example of bonding of the first substrate and the second substrate performed by the bonding unit.

### DETAILED DESCRIPTION OF THE PREFERRED EMBODIMENTS

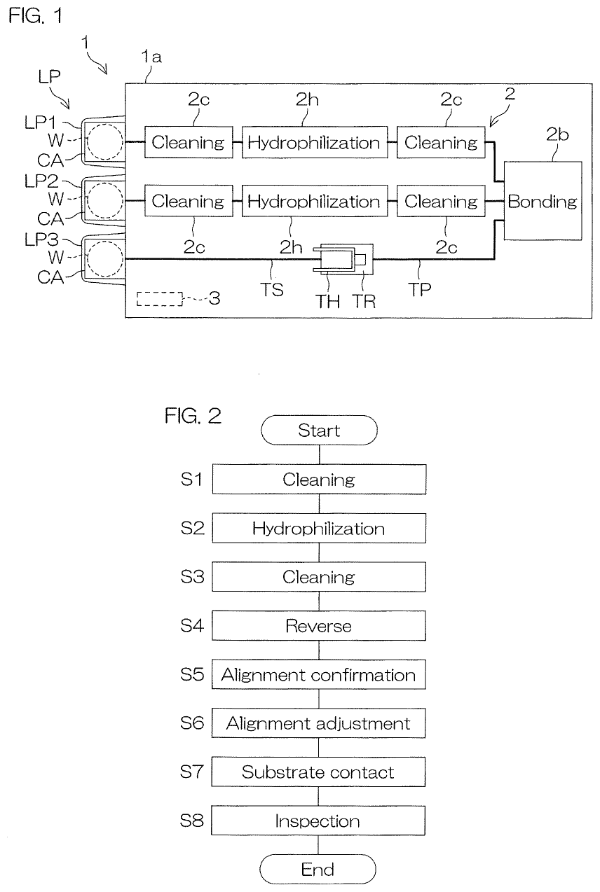

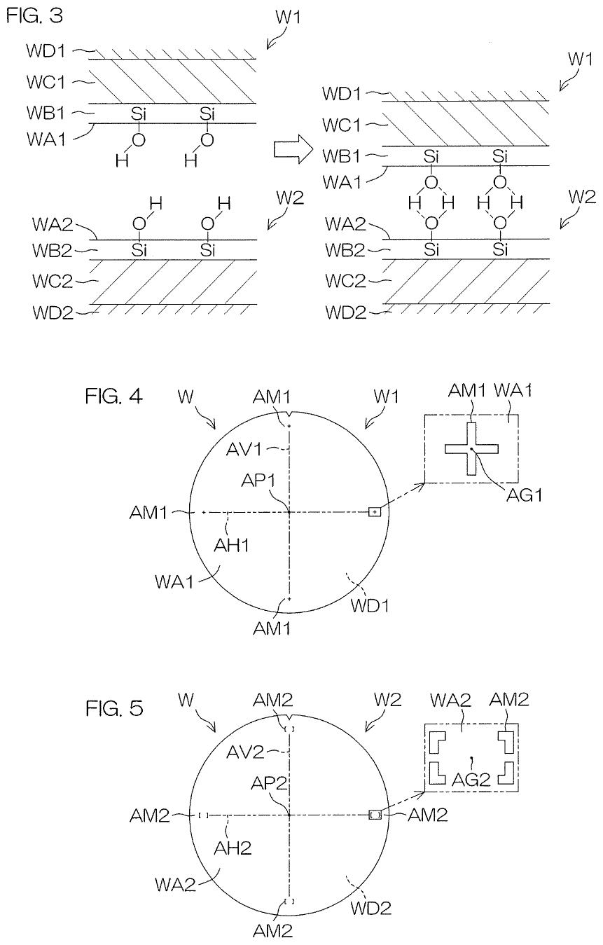

FIG. 1 is a schematic plan view of a substrate bonding apparatus 1 according to the first embodiment of the present invention. FIG. 2 is a process diagram for illustrating one example of a substrate bonding method performed by the substrate bonding apparatus 1. FIG. 3 is a schematic view showing one example of cross-sections of a first substrate W1 and a second substrate W2 before and after being bonded.

The substrate bonding apparatus 1 is an apparatus that bonds two disc-shaped substrates W. As shown in FIG. 1, the substrate bonding apparatus 1 includes a plurality of load ports LP on which a plurality of carriers CA housing a plurality of substrates W such as a FOUP (front-opening unified pod) are placed one by one, a plurality of processing units 2 that process the substrates W transferred from the plurality of load ports LP, and a transfer system TS that transfers the substrate W between the load port LP and the processing unit 2 or between two processing unit 2. The substrate bonding apparatus 1 further includes an outer wall 1a that forms a sealed space housing the plurality of processing units 2 and the transfer system TS and a controller 3 that controls the substrate bonding apparatus 1.

FIG. 1 shows an example where three load ports LP are provided. The three load ports LP include a first load port LP1 on which the carrier CA housing the first substrate W1 is placed, a second load port LP2 on which a carrier CA housing the second substrate W2 is placed, and a third load port LP3 on which a carrier CA housing the bonded first substrate W1 and second substrate W2 are placed. The first load port LP1 and the second load port LP2 are carry-in ports on which the carriers CA housing the substrates W to be bonded by the substrate bonding apparatus 1 are placed. The third load port LP3 is a carry-out port where the carrier CA housing the two substrates W bonded by the substrate bonding apparatus 1 is placed.

The transfer system TS transfers the first substrate W1 and the second substrate W2 to be bonded from the first load port LP1 and the second load port LP2 to the plurality of processing units 2 and transfers the first substrate W1 and the second substrate W2 bonded to each other from the plurality of processing units 2 to the third load port LP3. The transfer system TS may include at least one transfer robot TR that transfers one or more substrates W in a horizontal posture on a transfer path TP.

The transfer robot TR includes at least one hand TH that holds one substrate W in a horizontal posture. The transfer robot TR moves along the transfer path TP while horizontally holding the substrate W with the hand TH. Thick lines in FIG. 1 represent the transfer path TP. FIG. 1 shows an example where the transfer path TP extends from each of the first load port LP1 and the second load port LP2 to the plurality of processing units 2 and returns from the plurality of processing units 2 to the third load port LP3.

The plurality of processing units 2 include at least one cleaning unit 2c that cleans the substrates W to be bonded, and at least one hydrophilizing unit 2h that hydrophilizes bonding surfaces WA1 and WA2 (see FIG. 3) of the substrates W to be bonded. The plurality of processing units 2 further include a reversing unit that reverses one of the two substrates W to be bonded, a bonding unit 2b that brings the bonding surfaces WA1 and WA2 of the two substrates W into contact with each other, and an inspection unit that inspects bonding accuracy of the two substrates W. FIG. 1 shows an example in which the reversing unit and the inspection unit are a portion of the bonding unit 2b. The reversing unit may be a unit independent of the bonding unit 2b. The same applies to the inspection unit.

The plurality of processing units 2 may further include a heating unit that heats the two substrates W that has been bonded by the bonding unit 2b to increase the bonding strength of the two substrates W. The plurality of processing units 2 may further include at least one pre-aligner that reduces the difference between the actual position and angle of the substrate W and the ideal position and angle of the substrates W by adjusting the position and angle of the substrate W before being carried into the bonding unit 2b. The pre-aligner may adjust the position and angle of the substrate W based on the outer periphery of the substrate W, or may adjust the position and angle of the substrate W based on an alignment mark described below. The thickness of the substrate W to be bonded may be measured by the pre-aligner or the other processing unit 2.

An example of a procedure to bond two substrates W by the substrate bonding apparatus 1 is as follows Specifically, a pre-cleaning step (step S1 in FIG. 2) of cleaning and drying the first substrate W1 taken out from the carrier CA on the first load port LP1 and the second substrate W2 taken out from the carrier CA on the second load port LP2 is performed. Thereafter, a hydrophilization step (step S2 in FIG. 2) of hydrophilizing the bonding surfaces WA1 and WA2 of the two substrates W is performed, and a post-cleaning step (step S3 in FIG. 2) of cleaning and drying the two substrates W that have been hydrophilized is performed.

After the two hydrophilized substrates W are cleaned, a reversing step (step S4 in FIG. 2) of reversing one of the two substrates W is performed. Thereafter, an alignment confirmation step (step S5 in FIG. 2) of confirming the alignment of the two substrates W to be bonded, an alignment adjustment step (step S6 in FIG. 2) of adjusting the alignment of the two substrates W based on the confirmed alignment, and a substrate contact step (step S7 in FIG. 2) of bringing the two substrates W subjected to the alignment adjustment into contact with each other are performed. Thereafter, an inspection step (step S8 in FIG. 2) of inspecting the bonding accuracy of the two substrates W, that is, a deviation amount of the position of the bonded two substrates W and a deviation amount of the angle (angle around the center of the substrate W) of the bonded two substrates W is performed. Thereafter, the two bonded substrates W are housed in the carrier CA on the third load port LP3.

The pre-cleaning step may be a single substrate processing type cleaning in which a processing liquid such as a cleaning liquid is supplied to a plurality of substrates W one by one, or may be a batch type cleaning in which a processing liquid such as a cleaning liquid is simultaneously supplied to a plurality of substrates W arranged in parallel with each other at intervals. The same applies to the post-cleaning step. One of the pre-cleaning step and the post-cleaning step may be single substrate processing type cleaning, and the other of the pre-cleaning step and the post-cleaning step may be batch type cleaning.

The pre-cleaning step and the post-cleaning step may be performed in the same cleaning unit 2c, or may be performed in separate cleaning units 2c. The cleaning unit 2c that performs the pre-cleaning step of the first substrate W1 may be the same as or different from the cleaning unit 2c that performs the pre-cleaning step of the second substrate W2. The same applies to the post-cleaning step. FIG. 1 shows an example in which the pre-cleaning step and the post-cleaning step of the first substrate W1 and the pre-cleaning step and the post-cleaning step of the second substrate W2 are performed in separate cleaning units 2c.

The hydrophilization step may be plasma processing of irradiating the bonding surfaces WA1 and WA2 of the substrate W with plasma such as oxygen plasma. In this case, moisture in the air or moisture supplied to the substrate W in the post-cleaning step comes into contact with the bonding surfaces WA1 and WA2 of the substrate W irradiated with plasma, and a hydrophilic group such as a hydroxyl group (OH group) is formed on the bonding surfaces WA1 and WA2 of the substrate W. The hydrophilization step may be a wet treatment of supplying the bonding surfaces WA1 and WA2 of the substrate W with a hydrophilization liquid to form the hydrophilic group on the bonding surfaces WA1 and WA2 of the substrate W. In this case, the hydrophilizing unit 2h may perform at least one of the pre-cleaning step and the post-cleaning step in addition to the hydrophilizing step. When the hydrophilizing unit 2h performs both the pre-cleaning step and the post-cleaning step, the cleaning unit 2c may be omitted.

The hydrophilization step may be a single substrate processing type hydrophilization step of hydrophilizing a plurality of substrates W one by one, or may be a batch type hydrophilization step of simultaneously hydrophilizing a plurality of substrates W arranged in parallel with each other at intervals. The hydrophilizing unit 2h that performs the hydrophilization step of the first substrate W1 may be the same as or different from the hydrophilizing unit 2h that performs the hydrophilization step of the second substrate W2. FIG. 1 shows an example of the latter.

In the example shown in FIG. 1, the alignment confirmation step, the alignment adjustment step, and the substrate contact step are performed by the bonding unit 2b. In this example, the reversing step and the inspection step are also performed by the bonding unit 2b. The alignment confirmation step is a step of confirming alignment of two substrates W to be bonded on the basis of images of alignment marks (see FIG. 4) of the two substrates W. The substrate contact step is a step of bonding the two substrates W by bringing the two substrates W subjected to alignment adjustment into contact with each other. The allowable bonding accuracy (tolerance of the two bonded substrates W) is, for example, ±100 nm, and in some cases, ±10 nm.

The substrate contact step may be a step of directly bonding two substrates W in the atmosphere at room temperature. The substrate contact step may be a step of performing face-to-face bonding to bond the two substrates W such that the front surfaces of the substrates W face each other. In this case, the front surfaces of the two substrates W correspond to the bonding surfaces WA1 and WA2 of the two substrates W. The substrate contact step may be a step of bonding the two substrates W without pressing one of the two substrates W against the other of the two substrates W, or by pressing one of the two substrates W against the other of the two substrates W with a pressure that does not damage a device formed on the two substrates W.

FIG. 3 illustrates cross-sections of the first substrate W1 and the second substrate W2 cut along a plane orthogonal to the first substrate W1 and the second substrate W2. A ratio between thicknesses of device layers WC1 and WC2 and thicknesses of the bonding layers WB1 and WB2 shown in FIG. 3 is not necessarily the same as the actual ratio. £ The left side of FIG. 3 illustrates an example in which a hydroxyl group, which is an example of a hydrophilic group, is formed on the bonding surface WA1 of the first substrate W1 and the bonding surface WA2 of the second substrate W2 before being bonded. In this example, an oxygen atom (O) in the hydroxyl group is bonded to a silicon atom (Si) in the bonding layers WB1 and WB2.

The bonding surface WA1 of the first substrate W1 and the bonding surface WA2 of the second substrate W2 before being bonded are terminated with a plurality of hydroxyl groups. When the bonding surface WA1 of the first substrate W1 and the bonding surface WA2 of the second substrate W2 are brought into contact with each other, the first substrate W1 and the second substrate W2 are bonded by an intermolecular force acting between the two hydroxyl groups. In some cases, water molecules are separated from the two hydroxyl groups, and silicon atoms in the bonding layer WB1 of the first substrate W1 and silicon atoms in the bonding layer WB2 of the second substrate W2 are bonded through oxygen atoms. In this manner, the first substrate W1 and the second substrate W2 are bonded.

Next, the substrate W and the alignment mark will be described.

FIG. 4 is a schematic plan view of the first substrate W1 for illustrating a first alignment mark AM1 of the first substrate W1. FIG. 5 is a schematic plan view of the second substrate W2 for illustrating a second alignment mark AM2 of the second substrate W2.

In FIGS. 4 and 5, the first alignment mark AM1 and the second alignment mark AM2 are exaggerated for easy understanding. The size of the alignment mark with respect to the substrate W is not limited to the examples shown in FIGS. 4 and 5. The arrangement of the alignment marks with respect to the substrate W and the number of alignment marks provided on one substrate W are not limited to the examples shown in FIGS. 4 and 5.

As shown in FIGS. 4 and 5, the first substrate W1 and the second substrate W2 are flat disks having equal diameters. The diameters of the first substrate W1 and the second substrate W2 may be 300 mm or other diameters. The thermal expansion coefficient of the first substrate W1 may be equal to or different from the thermal expansion coefficient of the second substrate W2. The first substrate W1 includes a disk-shaped base material WD1, and the second substrate W2 includes a disk-shaped base material WD2 (see FIG. 3). The base material WD1 and the base material WD2 are made of a semiconductor such as a single crystal of silicon. The base material WD1 and the base material WD2 may be made of a substance other than a semiconductor.

Each of the base material WD1 and the base material WD2 includes a circular front surface and a circular rear surface parallel to each other, and an annular end surface connecting outer edges of the front surface and the rear surface. The front surface and the rear surface of the base material WD1 and the base material WD2 are flat surfaces parallel to each other. The front surfaces of the base material WD1 and the base material WD2 are device forming surfaces on which a device is formed. The rear surfaces of the base material WD1 and the base material WD2 are non-device forming surfaces on which no device is formed. Both the front surface and the rear surface of the base material WD1 or the base material WD2 may be the device forming surfaces.

An outer peripheral portion of the base material WD1 forms a V-shaped notch opened at the end surface of the base material WD1 when the base material WD1 is viewed in a direction orthogonal to the front surface of the base material WD1. The outer peripheral portion of the base material WD1 may form an orientation flat instead of the notch. The notch and the orientation flat indicate the crystal orientation of the base material WD1. The first substrate W1 is positioned in the circumferential direction of the first substrate W1 with reference to the notch or orientation flat of the first substrate W1. The same applies to the second substrate W2.

The first substrate W1 includes at least one first alignment mark AM1 serving as a reference when aligning the first substrate W1. The first substrate W1 further includes at least one device formed on the front surface of the base material WD1 such as a transistor or a capacitor. The first alignment mark AM1 may be a portion of the device or a structure unrelated to the device. The position of the first substrate W1 in the direction parallel to the front surface of the first substrate W1 and the angle of the first substrate W1 around the perpendicular line orthogonal to the central portion of the front surface of the first substrate W1 are specified based on at least one first alignment mark AM1 provided on the first substrate W1. The shape and number of the first alignment marks AM1 are arbitrary as long as the position of the first substrate W1 and the angle of the first substrate W1 can be specified. The same applies to the second alignment mark AM2.

The first substrate W1 includes a device layer WC1 (see FIG. 3) covering the front surface of the base material WD1 and a bonding layer WB1 (see FIG. 3) covering the front surface of the device layer WC1. The first alignment mark AM1 is arranged in the device layer WC1. A device such as a transistor is also disposed in the device layer WC1. The first alignment mark AM1 and the device are covered with the bonding layer WB1. The bonding layer WB1 is a transparent or translucent insulating layer. The bonding layer WB1 may be a silicon oxide film or a thin film of a substance other than silicon oxide. In the former case, the bonding layer WB1 may be a silicon oxide film manufactured using tetraethoxysilane (TEOS). The same applies to the second substrate W2.

The front surface and the rear surface of the first substrate W1 are two planes parallel to each other. The rear surface of the first substrate W1 is a plane opposite to the front surface of the first substrate W1. The bonding surface WA1 is a front surface of the first substrate W1 in contact with the atmosphere in the space in which the first substrate W1 is disposed. When the bonding surface WA1 of the first substrate W1 faces upward, the bonding surface WA1 of the first substrate W1 corresponds to the upper surface of the first substrate W1, and the rear surface of the first substrate WI corresponds to the lower surface of the first substrate W1. The front surface of the bonding layer WB1 corresponds to the bonding surface WA1 of the first substrate W1. The bonding surface WA1 may be a circular plane parallel to the front surface of the base material WD1, covering the entire area of the front surface of the base material WD1, or may be a plane parallel to the front surface of the base material WD1, covering only a portion of the front surface of the base material WD1. The same applies to the second substrate W2.

FIGS. 4 and 5 illustrate an example in which four first alignment marks AM1 having the same shape and size are provided on the first substrate W1, and four second alignment marks AM2 having the same shape and size are provided on the second substrate W2. FIG. 4 illustrates an example in which the first alignment mark AM1 has a cross shape. FIG. 5 illustrates an example in which the second alignment mark AM2 includes four L-shaped figures arranged one by one at each of the four corners of the rectangle along any two of the four sides of the rectangle.

The alignment mark may be configured by one continuous figure as shown in FIG. 4, or may be configured by a plurality of figures separated from each other as shown in FIG. 5. When a plurality of alignment marks are formed on one substrate W, the alignment marks may be circles or rings.

The alignment mark preferably has a shape that can specify the height direction and the width direction orthogonal to each other. The height direction and the width direction of the alignment mark are parallel to the front surface of the substrate W and are orthogonal to each other. When the alignment mark has a cross shape, a direction parallel to a longitudinal line of the alignment mark is a height direction of the alignment mark, and a direction parallel to a lateral line of the alignment mark is a width direction of the alignment mark. In FIG. 4, the vertical direction of the paper surface is the height direction of the alignment mark, and the horizontal direction of the paper surface is the width direction of the alignment mark. As shown in FIG. 5, when the alignment mark includes four L-shaped figures arranged at four corners of a horizontally long rectangle, a direction parallel to a short side of the rectangle is a height direction of the alignment mark, and a direction parallel to a long side of the rectangle is a width direction of the alignment mark.

The centers of gravity AGI of the four first alignment marks AM1 shown in FIG. 4 are arranged at intervals of 90 degrees on a circle concentric with the first substrate W1. Similarly, the centers of gravity AG2 of the four second alignment marks AM2 shown in FIG. 5 are arranged at intervals of 90 degrees on a circle concentric with the second substrate W2. A vertical axis AV1, a horizontal axis AH1, and a reference point AP1 of the first substrate W1 are specified based on the four first alignment marks AM1 shown in FIG. 4. A vertical axis AV2, a horizontal axis AH2, and a reference point AP2 of the second substrate W2 are specified based on the four second alignment marks AM2 shown in FIG. 5.

The vertical axis AV1, the horizontal axis AH1, and the reference point AP1 of the first substrate W1 are all virtual straight lines or points set on the front surface of the first substrate W1. The vertical axis AV1 and the horizontal axis AH1 are reference lines indicating the angle of the first substrate W1. The vertical axis AV1 is a straight line passing through the centers of gravity AG1 of the two first alignment marks AM1 having different angles of 180 degrees around the center of the first substrate W1. The horizontal axis AH1 is a straight line passing through the centers of gravity AG1 of the remaining two first alignment marks AM1. The vertical axis AV1 and the horizontal axis AH1 are straight lines orthogonal to each other. The reference point AP1 is an intersection of the vertical axis AV1 and the horizontal axis AH1. The center of the first substrate W1 is specified based on the contour of the first substrate W1. The reference point AP1 may or may not coincide with the center of the first substrate W1.

The vertical axis AV2, the horizontal axis AH2, and the reference point AP2 of the second substrate W2 are all virtual straight lines or points set on the front surface of the second substrate W2. The vertical axis AV2 and the horizontal axis AH2 are reference lines indicating the angle of the second substrate W2. The vertical axis AV2 is a straight line passing through the centers of gravity AG2 of the two second alignment marks AM2 having different angles of 180 degrees around the center of the second substrate W2. The horizontal axis AH2 is a straight line passing through the centers of gravity AG2 of the remaining two second alignment marks AM2. The vertical axis AV2 and the horizontal axis AH2 are straight lines orthogonal to each other. The reference point AP2 is an intersection of the vertical axis AV2 and the horizontal axis AH2. The center of the second substrate W2 is specified based on the contour of the second substrate W2. The reference point AP2 may or may not coincide with the center of the second substrate W2.

When the two substrates W, that is, the first substrate W1 and the second substrate W2 are bonded, alignment adjustment is performed to minimize the positional deviation between the first substrate W1 and the second substrate W2 in a state where the bonding surface WA1 of the first substrate W1 and the bonding surface WA2 of the second substrate W2 face each other vertically. In the example shown in FIGS. 4 and 5, the relative position between the first substrate W1 and the second substrate W2 is adjusted such that the distance between the reference point AP1 of the first substrate W1 and the reference point AP2 of the second substrate W2 decreases, the angle between the horizontal axis AH1 of the first substrate W1 and the horizontal axis AH2 of the second substrate W2 decreases, and the angle between the vertical axis AV1 of the first substrate W1 and the vertical axis AV2 of the second substrate W2 decreases.

The minimization of the positional deviation between the first substrate W1 and the second substrate W2 may be determined by comprehensively considering the distance between the reference point AP1 and the reference point AP2, which are two reference points, the angle between the vertical axis AV1 and the vertical axis AV2, which are two vertical axes, and the angle between the horizontal axis AH1 and the horizontal axis AH2, which are two horizontal axes. That is, when the positional deviation between the first substrate W1 and the second substrate W2 is minimized, at least one of the distance between the reference point AP1 and the reference point AP2, which are the two reference points, the angle between the vertical axis AV1 and the vertical axis AV2, which are the two vertical axes, and the angle between the horizontal axis AH1 and the horizontal axis AH2, which are the two horizontal axes, is not necessarily minimized.

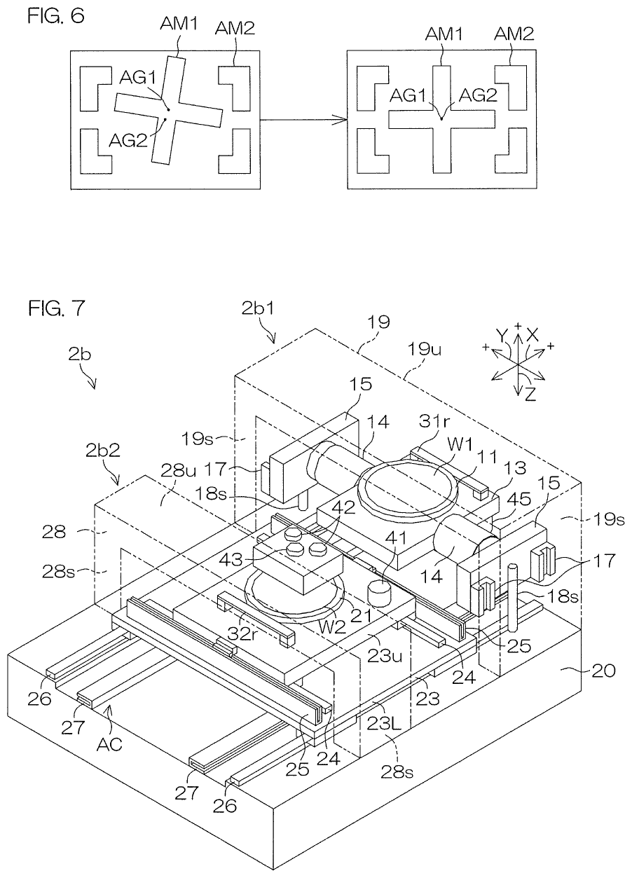

The method to adjust alignment of the first substrate W1 and the second substrate W2 is not limited to the above. For example, in a case where the same number of three or more alignment marks are provided on each of the first substrate W1 and the second substrate W2, the relative position between the first substrate W1 and the second substrate W2 may be adjusted such that the total or average value of the intervals between the center of gravity AG1 of the first alignment mark AM1 on the first substrate W1 and the center of gravity AG2 of the second alignment mark AM2 on the second substrate W2 is minimized without using the reference lines such as the vertical axis AV1 and the vertical axis AV2 and the horizontal axis AH1 and the horizontal axis AH2. Alternatively, the relative position between the first substrate W1 and the second substrate W2 may be adjusted such that the interval between the approximate curve or the straight line obtained from the centers of gravity AG1 of the plurality of first alignment marks AM1 on the first substrate W1 using a calculation method such as a least squares method and the approximate curve or the straight line obtained from the centers of gravity AG2 of the plurality of second alignment marks AM2 on the second substrate W2 using the same calculation method is minimized.
FIG. 6 is a schematic view showing the first alignment mark AM1 and the second alignment mark AM2 before and after alignment adjustment of the first substrate W1 and the second substrate W2. The left side of FIG. illustrates the first alignment mark AM1 and the second alignment mark AM2 before alignment adjustment of the first substrate W1 and the second substrate W2. In this example, the center of gravity AG1 of the first alignment mark AM1 is shifted with respect to the center of gravity AG2 of the second alignment mark AM2, and the first alignment mark AM1 is inclined with respect to the second alignment mark AM2. As illustrated on the right side of FIG. 6, when the alignment adjustment is performed, the center of gravity AG1 of the first alignment mark AM1 coincides with the center of gravity AG2 of the second alignment mark AM2, and the direction of the first alignment mark AM1 coincides with the direction of the second alignment mark AM2.

Next, the bonding unit 2b will be described.

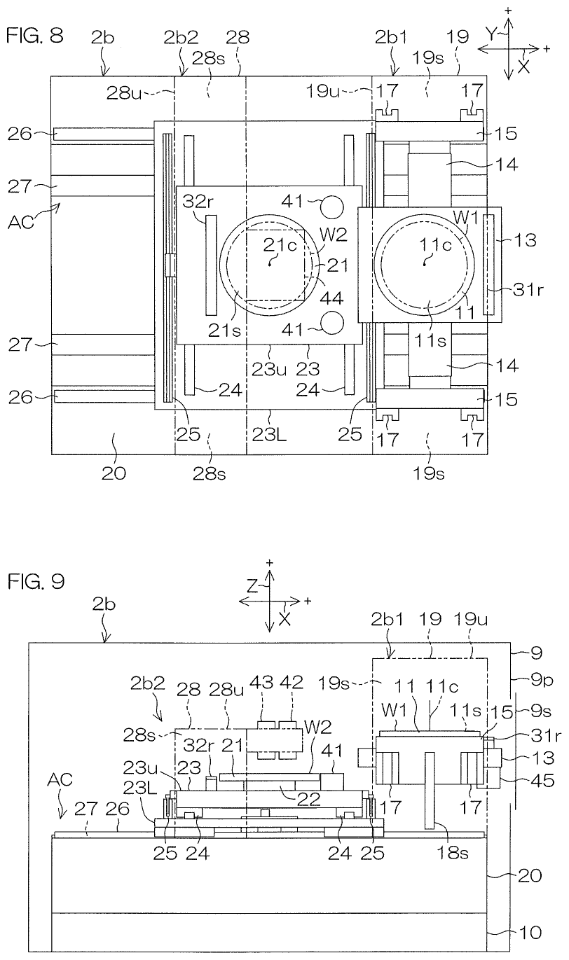

FIG. 7 is a perspective view of the bonding unit 2b. FIG. 8 is a plan view of the bonding unit 2b. FIG. 9 is a view of the bonding unit 2b as viewed horizontally in the Y direction.

In the following example, a first chuck 11 is rotatable around a horizontal straight line. Hereinafter, unless otherwise specified, the first chuck 11 in the loading/unloading state will be described. In the loading/unloading state of the first chuck 11, a center line 11c (see FIG. 9) of the first chuck 11 is vertical, and a first suction surface 11s (see FIG. 9) of the first chuck 11 is directed upward.

The X direction and the Y direction are horizontal directions orthogonal to each other. The Z direction is a vertical direction orthogonal to the X direction and the Y direction. The X direction, the Y direction, and the Z direction correspond to the left-right direction, the front-rear direction, and the up-down direction of the bonding unit 2b, respectively. The positive sides in the X direction, the Y direction, and the Z direction correspond to the right direction, the front direction, and the upper direction of the bonding unit 2b, respectively.

As shown in FIGS. 7 to 9, the bonding unit 2b includes a first bonding module 2b1 including the first chuck 11 that holds the first substrate W1, a second bonding module 2b2 including a second chuck 21 that holds the second substrate W2, an actuator mechanism AC that moves at least one of the first chuck 11 and the second chuck 21, and a base 20 that supports the first bonding module 2b1 and the second bonding module 2b2.

The first chuck 11 and the second chuck 21 are disposed above the base 20. The base 20 is disposed between a floor surface of a clean room in which the substrate bonding apparatus 1 is installed and the first chuck 11 and the second chuck 21. The base 20 is a component common to the first bonding module 2b1 and the second bonding module 2b2. The base 20 may be an integral member or may include a plurality of members fixed to each other.

As shown in FIG. 9, the bonding unit 2b may include a vibration removal board 10 that reduces vibration of the base 20. The vibration removal board 10 may include a vibration sensor that detects vibration of at least one of the floor surface of the clean room and the base 20, and a vibration removal actuator that reduces vibration of the base 20 by moving the base 20 based on a detection value of the vibration sensor. The vibration removal board 10 is disposed between the floor surface of the clean room and the base 20. The base 20 is supported by the vibration removal board 10.

The bonding unit 2b may include a chamber 9 that houses the first chuck 11 and the second chuck 21. The chamber 9 includes a box-shaped partition wall 9p provided with a carry-in/carry-out port through which the substrate W passes, and a shutter 9s that opens and closes the carry-in/carry-out port. The partition wall 9p may include one carry-in/carry-out port through which both the first substrate W1 and the second substrate W2 pass, or may include a carry-in/carry-out port through which the first substrate W1 passes and a carry-in/carry-out port through which the second substrate W2 passes. In the latter case, the shutter 9s may be provided for each carry-in/carry-out port. Equipment in the chamber 9, such as the first chuck 11, is separated by the chamber 9 from the processing unit 2 other than the bonding unit 2b, such as the cleaning unit 2c (see FIG. 1).

At least one of the first chuck 11 and the second chuck 21 is movable in the Y direction with respect to the base 20. Similarly, at least one of the first chuck 11 and the second chuck 21 is movable in the X direction with respect to the base 20. At least one of the first chuck 11 and the second chuck 21 is movable in the Z direction with respect to the base 20. FIGS. 7 to 9 illustrate examples in which the first chuck 11 is movable in the Z direction with respect to the base 20, and the second chuck 21 is movable in the X direction and the Y direction with respect to the base 20.

As long as the first chuck 11 and the second chuck 21 are relatively movable in the X direction, the Y direction, and the Z direction, the direction in which the first chuck 11 and the second chuck 21 can move with respect to the base 20 is not limited to the above. For example, if one of the first chuck 11 and the second chuck 21 is movable in the X direction, the Y direction, and the Z direction with respect to the base 20, the other of the first chuck 11 and the second chuck 21 may not be movable in the X direction, the Y direction, and the Z direction with respect to the base 20.

The first chuck 11 and the second chuck 21 are a vacuum chuck that holds the first substrate W1 with a suction force generated by suction of gas, or an electrostatic chuck that holds the first substrate W1 with an electrical suction force. As long as the first substrate W1 and the second substrate W2 can be fixed to the first chuck 11 and the second chuck 21, the first chuck 11 and the second chuck 21 may be chucks other than these chucks.

As shown in FIG. 8, the first chuck 11 includes a first suction surface 11s in contact with the lower surface of the first substrate W1. Similarly, the second chuck 21 includes a second suction surface 21s in contact with the lower surface of the second substrate W2. The center line 11c of the first chuck 11 is a straight line that passes through the center of the first suction surface 11s and is orthogonal to the first suction surface 11s. The center line 21c of the second chuck 21 is a straight line that passes through the center of the second suction surface 21s and is orthogonal to the second suction surface 21s.

FIGS. 7 to 9 illustrate examples in which each of the first suction surface 11s and the second suction surface 21s is a circular horizontal plane having a diameter equal to or larger than the diameter of the first substrate W1 and the second substrate W2. In this example, the first substrate W1 is placed on the first suction surface 11s such that the center of the first substrate W1 coincides with the center of the first suction surface 11s. Similarly, the second substrate W2 is placed on the second suction surface 21s such that the center of the second substrate W2 coincides with the center of the second suction surface 21s. Thereby, the lower surface of the first substrate W1 comes into contact with the first suction surface 11s, and the lower surface of the second substrate W2 comes into contact with the second suction surface 21s.

The first suction surface 11s may have a shape other than a circular shape or a shape other than a horizontal plane. The same applies to the second suction surface 21s. For example, when the first chuck 11 is in the loading/unloading state, the first suction surface 11s may be a spherical cap-shaped curved surface convex upward or a circular curved surface curved in an arc shape, or may include a horizontal portion and a non-horizontal portion. The same applies to the second suction surface 21s. The non-horizontal portion may be a plane inclined at a certain angle with respect to the horizontal plane, a curved surface in which an inclination angle with respect to the horizontal plane continuously changes, or a plane other than these. One of the first suction surface 11s and the second suction surface 21s may be a horizontal plane, and the other of the first suction surface 11s and the second suction surface 21s may have a shape other than the horizontal plane.

The first substrate W1 and the second substrate W2 when carried into the bonding unit 2b are flat. Even if the first substrate W1 and the second substrate W2 are warped, the amount of warpage is so small that the first substrate W1 and the second substrate W2 can be regarded as substantially flat. In a case where the first suction surface 11s has a shape other than a horizontal plane, when the first substrate W1 is placed on the first chuck 11, the first suction surface 11s partially contacts the lower surface of the first substrate W1, and a gap is formed between the lower surface of the first substrate W1 and the first suction surface 11s of the first chuck 11. When the first chuck 11 sucks the first substrate W1, the upper surface and the lower surface of the first substrate W1 are elastically deformed into the same or substantially the same shape as the first suction surface 11s, and the contact area between the lower surface of the first substrate W1 and the first suction surface 11s of the first chuck 11 increases. The same applies to a case where the second suction surface 21s has a shape other than a horizontal plane.

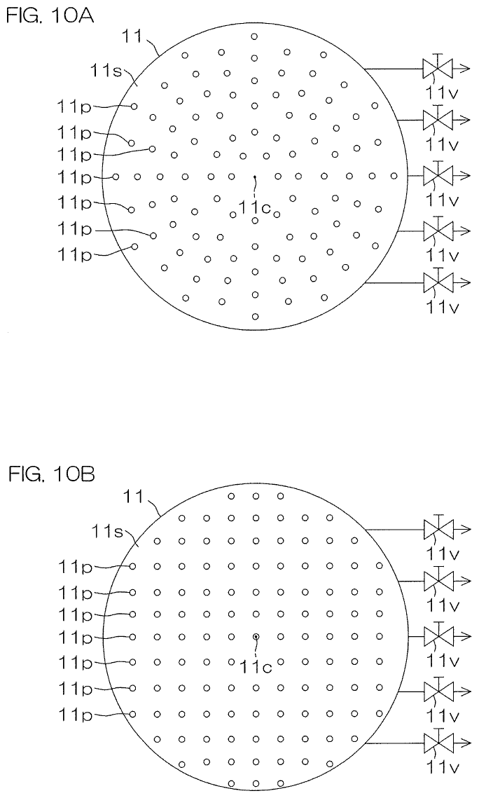

The first suction surface 11s may include a plurality of suction regions that generate and stop suction forces to hold the first substrate W1 on the first suction surface 11s independently of each other. The same applies to the second suction surface 21s. The suction region is a region that generates a suction force regardless of whether or not another suction region generates a suction force. The plurality of suction regions of the first suction surface 11s may extend radially from the center of the first suction surface 11s as shown in FIG. 10A, or may extend along a plurality of straight lines parallel to each other across the first suction surface 11s as shown in FIG. 10B. The arrangement and shape of the plurality of suction regions of the first suction surface 11s may be other than these. The same applies to the plurality of suction regions of the second suction surface 21s.

FIG. 10 A and 10B are schematic plan views of the first chuck 11. FIGS. 10A and 10B illustrate examples in which the first chuck 11 is a vacuum chuck, and the first suction surface 11s includes a plurality of suction regions. A plurality of suction ports 11p to suck gas are opened on the first suction surface 11s. In the example shown in FIG. 10A, the plurality of suction ports 11p are arranged on a plurality of straight lines radially extending from the center of the first suction surface 11s. In the example shown in FIG. 10B, the plurality of suction ports 11p are arranged on a plurality of straight lines parallel to each other across the first suction surface 11s. FIG. 10B illustrates an example in which the plurality of suction ports 11p are arranged at equal intervals in the longitudinal direction and the lateral direction.

When the first chuck 11 or the second chuck 21 is a vacuum chuck, one or more suction ports 11p and a valve 11v may be provided for each suction region. When the first chuck 11 or the second chuck 21 is an electrostatic chuck, a plurality of electrodes corresponding to the plurality of suction regions on a one-to-one basis may be provided. When the valve 11v is opened, one or more suction ports 11p opened in the suction region corresponding to the valve 11v start suction of gas. When the valve 11v is closed, one or more suction ports 11p opened in the suction region corresponding to the valve 11v stop suction of gas. When the application of the voltage to the electrode is started, the suction region corresponding to the electrode starts to generate the electric suction force. When the application of the voltage to the electrode is stopped, the suction region corresponding to the electrode stops the generation of the electric suction force. Thereby, the plurality of suction regions generate and stop the suction force independently of each other.

Next, the first bonding module 2b1 will be described.

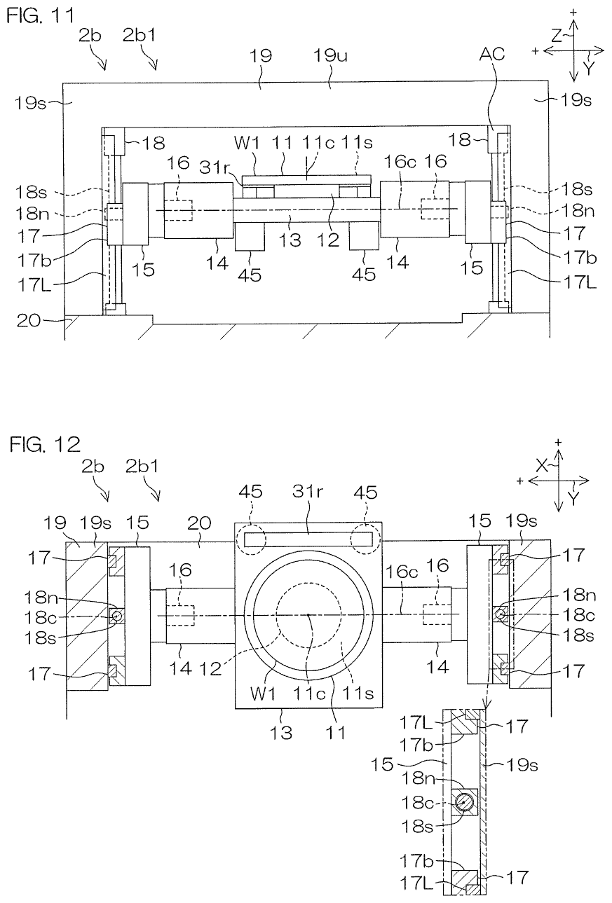

FIG. 11 is a view of the first bonding module 2bl as viewed horizontally in the X direction. FIG. 12 is a plan view of the first bonding module 2b1. As shown in FIGS. 11 and 12, the first bonding module 2bl includes a first stage 13 that is movable in parallel with the base 20 in the Z direction together with the first chuck 11. The first bonding module 2b1 further includes a pair of support shafts 14 supporting the first chuck 11 through the first stage 13, a pair of support bases 15, and a first frame 19. The first stage 13 may be a horizontal flat plate.

The first frame 19 includes a pair of first side frames 19s extending upward from the upper surface of the base 20, and a first upper frame 19u extending from one first side frame 19s to the other first side frame 19s in a state of being separated upward from the base 20. FIG. 11 illustrates an example in which the first frame 19 has a gate-shaped configuration. In this example, the first upper frame 19u connects the upper ends of the pair of first side frames 19s.

The pair of first side frames 19s are fixed to the base 20. The first upper frame 19u is fixed to the pair of first side frames 19s. The pair of first side frames 19s face each other in the Y direction with a space therebetween. The first upper frame 19u faces the upper surface of the base 20 in the Z direction at an interval. The pair of first side frames 19s are disposed on both sides of the first chuck 11, the first stage 13, the pair of support shafts 14, and the pair of support bases 15 in the Y direction. The first upper frame 19u is disposed above the first chuck 11, the first stage 13, the pair of support shafts 14, and the pair of support bases 15 so as to overlap the first chuck 11, the first stage 13, the pair of support shafts 14, and the pair of support bases 15 in a plan view.

The first chuck 11, the first stage 13, the pair of support shafts 14, and the pair of support bases 15 are supported by the first frame 19 in a state of being separated upward from the base 20. The pair of support bases 15 are disposed between the pair of first side frames 19s in the Y direction. The pair of support shafts 14 are disposed between the pair of support bases 15 in the Y direction. The first stage 13 is disposed between the pair of support shafts 14 in the Y direction. The pair of support bases 15 are supported by the pair of first side frames 19 s. The pair of support shafts 14 are supported by the pair of support bases 15 in a horizontal posture in which a center line of the pair of support shafts 14 is parallel to the Y direction. The first stage 13 is supported by the pair of support shafts 14 in a posture in which the center line 11c of the first chuck 11 is vertical.

The first bonding module 2bl includes a plurality of linear guides 17 that linearly guide the pair of support bases 15 in the Z direction with respect to the first frame 19. At least one linear guide 17 is disposed for each support base 15. FIG. 12 illustrates an example in which two linear guides 17 are arranged for each support base 15. The linear guide 17 includes a rail 17L extending linearly in the length direction, a slide block 17b moving in the length direction of the rail 17L along the rail 17L, and a plurality of balls interposed between the rail 17L and the slide block 17b. The rail 17L is fixed to the first side frame 19s in a posture parallel to the Z direction. The slide block 17b is fixed to the support base 15.

The actuator mechanism AC includes at least one Z actuator 18 that relatively moves the first chuck 11 and the second chuck 21 in the Z direction. FIG. 11 illustrates an example in which at least one Z actuator 18 moves the pair of support bases 15 in the Z direction and moves the first substrate W1 held by the first chuck 11 in the Z direction. At least one Z actuator 18 may be provided only on one support base 15, or at least one Z actuator may be provided for each support base 15. FIG. 11 illustrates an example in which one Z actuator 18 is provided for each support base 15.

The actuator is a device that converts electrical, fluid, magnetic, thermal, or chemical energy to mechanical work. The actuator includes an electric motor (rotary motor), a linear motor, an air cylinder, and other devices. The Z actuator 18 may be an electric motor or a linear motor, or may be an actuator other than this. FIGS. 11 and 12 illustrate an example in which the Z actuator 18 is an electric motor.

The power of the Z actuator 18 is transmitted to the first chuck 11 through a transmission mechanism including a drive body and a driven body. FIGS. 11 and 12 illustrate an example in which the drive body is a ball screw 18s and the driven body is a ball nut 18n. The drive body and the driven body may be members other than the ball screw 18s and the ball nut 18n such as a rack and a pinion.

As shown in FIG. 12, the ball screw 18s and the ball nut 18n are disposed between the first side frame 19s and the support base 15. The ball nut 18n is fixed to the support base 15. The ball nut 18n is connected to the ball screw 18s through a plurality of balls. The two ball screws 18s are disposed at two positions at which angles around the center line 11c of the first chuck 11 are different from each other by 180 degrees. The center lines 18c of the two ball screws 18s extend vertically in one plane extending in the Y direction and the Z direction.

When an electric motor as an example of the Z actuator 18 rotates the ball screw 18s, the ball nut 18n moves in the Z direction along the ball screw 18s. The ball nut 18n and the support base 15 move in the Z direction by a movement amount corresponding to the rotation angle of the Z actuator 18. When the two Z actuators 18 rotate in the same direction and at the same angle, the two ball nuts 18n move in the Z direction by the same amount. Thereby, the first substrate W1 held by the first chuck 11 rises or falls in the Z direction.

The actuator mechanism AC includes a first rotation motor 12 that rotates the first chuck 11 with respect to the first stage 13 around the center line 11c of the first chuck 11 corresponding to a rotation axis. The first rotation motor 12 is an electric motor. The first rotation motor 12 is disposed between the first chuck 11 and the first stage 13. The first rotation motor 12 is connected to the first chuck 11 and the first stage 13. The first substrate W1 is held by the first chuck 11 such that the center of the first substrate W1 is located on the center line 11c of the first chuck 11. When the first rotation motor 12 rotates in this state, the first substrate W1 and the first chuck 11 rotate with respect to the first stage 13 at the same angle in the same direction as the first rotation motor 12.

The actuator mechanism AC includes at least one reverse actuator 16 that rotates the first chuck 11 around a horizontal reversing center 16c. FIGS. 11 and 12 show an example in which the reverse actuator 16 is disposed in the support shaft 14. In this example, the reverse actuator 16 is disposed above the base 20 so as to overlap the base 20 in a plan view. The reverse actuator 16 may be disposed outside the support shaft 14. One reverse actuator 16 may be provided only for one support shaft 14, or one reverse actuator 16 may be provided for each support shaft 14. FIGS. 11 and 12 illustrate an example of the latter.

The reverse actuator 16 is an electric motor. The reverse actuator 16 may be an actuator other than the electric motor. In the example shown in FIGS. 11 and 12, the reverse actuator 16 rotates the first chuck 11 by rotating the first stage 13 around the center line of the pair of support shafts 14. The center line of the pair of support shafts 14 corresponds to a reversing center 16c. Therefore, the first chuck 11 and the first stage 13 rotate around a horizontal reversing center 16c extending in the Y direction. The reversing center 16c is a horizontal straight line passing through the center line 18c (see FIG. 12) of the two ball screws 18s. When the reverse actuator 16 rotates 180 degrees, the first chuck 11 and the first stage 13 rotate 180 degrees and face downward. Thereby, the first substrate W1 held by the first chuck 11 is reversed.

The first stage 13 may be fixed to the pair of support shafts 14, or may be rotatable with respect to the pair of support shafts 14 around the reversing center 16c. In the former case, the reverse actuator 16 rotates the pair of support shafts 14 with respect to the pair of support bases 15 to rotate the first stage 13 and the first chuck 11 around the reversing center 16c. In the latter case, the reverse actuator 16 rotates the first chuck 11 around the reversing center 16c by rotating the first stage 13 with respect to the pair of support shafts 14.

The first chuck 11 and the first stage 13 are movable in the Z direction with respect to the base 20 and the first frame 19. The range in which the first chuck 11 and the first stage 13 are movable in the Z direction includes a position where a rotating object such as the first stage 13 does not collide with the base 20 and the first frame 19 even when the first chuck 11 and the first stage 13 rotate 180 degrees around the reversing center 16c. The sizes of the first stage 13 and the first frame 19 may be set such that a rotating object does not collide with the base 20 and the first frame 19 even when the first chuck 11 and the first stage 13 rotate at any position in the Z direction.

The reverse actuator 16 is a portion of the reversing unit. The reverse actuator 16 reverses the first substrate W1 by rotating the first chuck 11 around the reversing center 16c by 180 degrees in a state where the first substrate W1 is held by the first chuck 11. As described below, the first chuck 11 holds the first substrate W1 when the first substrate W1 is bonded to the second substrate W2. Therefore, the first substrate W1 is held by the first chuck 11 before being reversed, and is also held by the first chuck 11 when bonded to the second substrate W2.

The reverse actuator 16 is an example of a posture changing actuator that changes the posture of the substrate W. The above-described two Z actuators 18 are also examples of the posture changing actuator. When the two Z actuators 18 arrange the two ball nuts 18n at different heights within a range of mechanical play of the mechanism to support the first chuck 11, the center line 11c of the first chuck 11 is inclined in the Y direction. Thereby, the posture of the first substrate W1 held by the first chuck 11 changes.

Next, a first fixed reference 31r will be described.

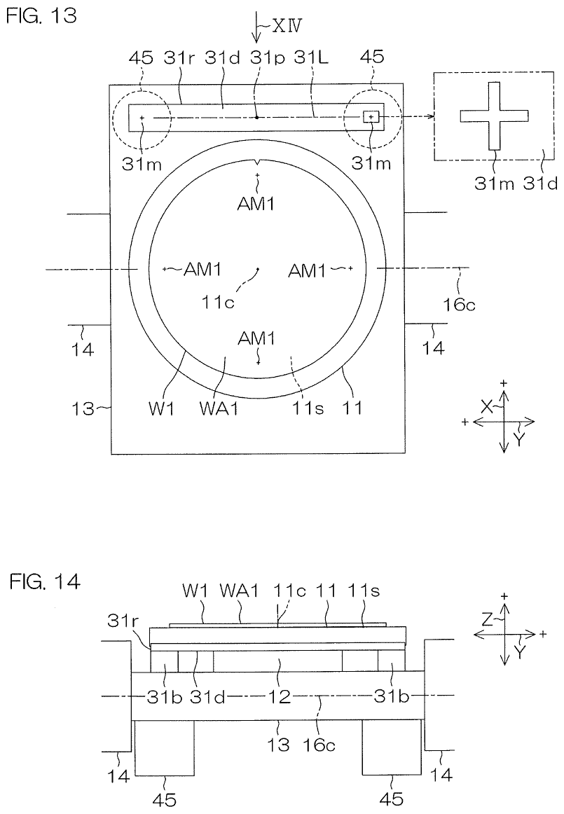

FIG. 13 is a plan view of the first stage 13. FIG. 14 is a horizontal view of the first stage 13 in a direction of an arrow XIV shown in FIG. 13. As shown in FIGS. 13 and 14, the first bonding module 2b1 includes a first fixed reference 31r serving as an indirect reference in aligning the first substrate W1. The first fixed reference 31r includes at least one first reference mark 31m serving as an indirect reference when the first substrate W1 is aligned, and a first display plate 31d on which at least one first reference mark 31m is marked.

FIG. 13 illustrates an example in which two first reference marks 31m having the same shape and size are provided. In this example, the first reference mark 31m has a cross shape. The first reference mark 31m may have a shape other than a cross. The first reference mark 31m may be formed on the first display plate 31d by photolithography, or may be formed on the first display plate 31d by another method such as laser marking.

In the example shown in FIG. 13, the first display plate 31d is a horizontal rectangular flat plate extending in the Y direction, and two first reference marks 31m are marked one by one at both ends of the first display plate 31d in the Y direction. Two long sides of the first display plate 31d extend in the Y direction, and two short sides of the first display plate 31d extend in the X direction. As shown in FIG. 14, in this example, the first display plate 31d is supported by the first stage 13 through two first support blocks 31b. An upper surface and a lower surface of the first display plate 31d are two horizontal planes parallel to each other. The lower surface of the first display plate 31d faces the horizontal and flat upper surface of the first stage 13 in the Z direction at an interval. The lower surface of the first display plate 31d may be in contact with the upper surface of the first stage 13.

The shape and arrangement of first display plate 31d and the number and arrangement of first reference marks 31m are not limited to the examples shown in FIGS. 13 and 14. For example, the first display plate 31d may be rotated by 90 degrees in the horizontal plane such that the long side of the first display plate 31d extends in the X direction. The first display plate 31d may include a horizontal rectangular longitudinal plate extending in the Y direction and a horizontal rectangular lateral plate extending in the X direction. The longitudinal plate and the lateral plate may be in contact with each other or may be separated from each other. When the first display plate 31d includes the longitudinal plate and the lateral plate, three or more first reference marks 31m may be arranged so as to be aligned in the X direction and the Y direction. For example, a second first reference mark 31m may be arranged on a horizontal straight line that passes through the first reference mark 31m and is parallel to the X direction, and a third first reference mark 31m may be arranged on a horizontal straight line that passes through the first reference mark 31m and is parallel to the Y direction.

The at least one first reference mark 31m is used to set a first fixed point 31p and a first fixed line 31L as indirect references when the first substrate W1 is aligned. The first fixed point 31p and the first fixed line 31L are virtual point and line. In the example shown in FIG. 13, a horizontal straight line passing through the centers of gravity of the two cross-shaped first reference marks 31m is set as the first fixed line 31L of the first stage 13. The first fixed point 31p of the first stage 13 may be the center of gravity of one first reference mark 31m or a random point on the first fixed line 31L, or may be any of other points.

As shown in FIG. 13, the first fixed reference 31r is disposed above the first stage 13 such that the first fixed reference 31r overlaps the first stage 13 in a plan view. The first fixed reference 31r is fixed to the first stage 13. An upper end of the first fixed reference 31r is disposed below the first substrate W1 on the first chuck 11. In a state where the first substrate W1 is held by the first chuck 11, the first fixed reference 31r does not overlap the first substrate W1 held by the first chuck 11 when viewed in the direction of the center line 11c of the first chuck 11. Therefore, when the first stage 13 is viewed in the direction of the center line 11c of the first chuck 11 in this state, not only the first reference mark 31m but also the first alignment mark AM1 of the first substrate W1 can be photographed by a camera.

As will be described below, at least one first alignment mark AM1 of the first substrate W1 held by the first chuck 11 is photographed by the camera. The camera also photographs at least one first reference mark 31m of the first fixed reference 31r. The position and angle of the first substrate W1 in the horizontal plane are specified based on the image of at least one first alignment mark AM1 photographed by the camera. The position and angle of the first fixed reference 31r in the horizontal plane are also identified based on the image of the at least one first reference mark 31m photographed by the camera. Furthermore, the relative position and angle between the first substrate W1 and the first fixed reference 31r are also specified based on the images of the first alignment mark AM1 and the first reference mark 31m. Therefore, if the position and angle of the first fixed reference 31r can be acquired, the position and angle of the first substrate W1 held by the first chuck 11 can also be acquired. These pieces of information are stored in the controller 3 (see FIG. 1).

Next, the second bonding module 2b2 will be described.

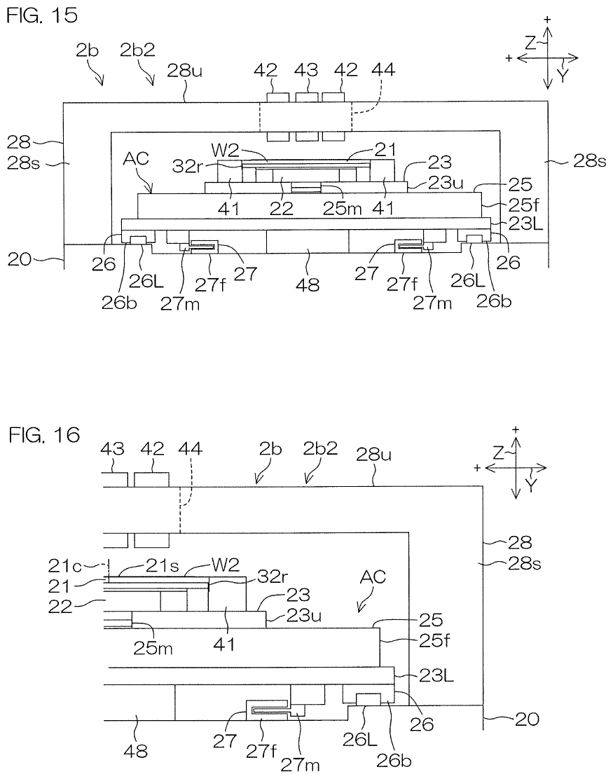

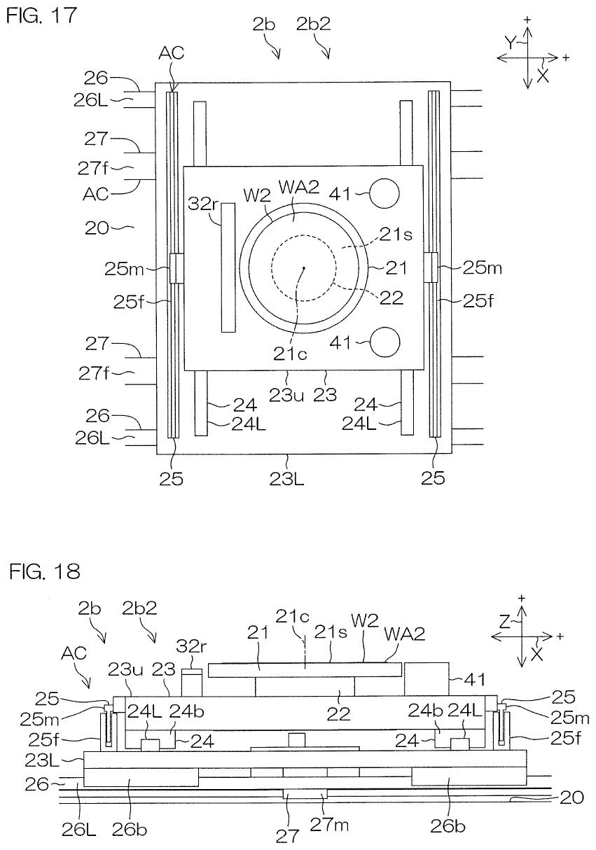

FIG. 15 is a view of the second bonding module 2b2 as viewed horizontally in the X direction. FIG. 16 is an enlarged view of a portion of FIG. 15. FIG. 17 is a plan view of the second bonding module 2b2. FIG. 18 is a view of the second bonding module 2b2 as viewed horizontally in the Y direction.

As shown in FIGS. 15 to 17, the second bonding module 2b2 includes a second stage 23 that is movable in parallel with the base 20 in the X direction and the Y direction together with the second chuck 21. The second stage 23 includes an upper stage 23u disposed between the second chuck 21 and the base 20, and a lower stage 23L disposed between the upper stage 23u and the base 20. FIGS. 15 to 17 illustrate an example in which the upper stage 23u is a Y stage movable in parallel in the Y direction with respect to the base 20, and the lower stage 23L is an X stage movable in parallel in the X direction with respect to the base 20. The lower stage 23L is larger than the upper stage 23u. One or both of the upper stage 23u and the lower stage 23L may be a horizontal flat plate.

The second bonding module 2b2 includes at least one linear guide 26 that linearly guides the lower stage 23L in the X direction with respect to the base 20. FIG. 15 illustrates an example in which two linear guides 26 are provided. The two linear guides 26 are disposed on the base 20. The lower stage 23L is disposed on the two linear guides 26. As shown in FIG. 16, the linear guide 26 includes a rail 26L extending linearly in the length direction, a slide block 26b moving in the length direction of the rail 26L along the rail 26L, and a plurality of balls interposed between the rail 26L and the slide block 26b. The rail 26L is fixed to the base 20 in a posture parallel to the X direction. The slide block 26b is fixed to the lower stage 23L.

The actuator mechanism AC includes at least one X actuator 27 that relatively moves the first chuck 11 and the second chuck 21 in the X direction. FIG. 15 illustrates an example in which at least one X actuator 27 moves the lower stage 23L in the X direction to move the second substrate W2 held by the second chuck 21 in the X direction. In this example, two X actuators 27 are provided, each X actuator 27 being a linear motor. As shown in FIG. 16, the linear motor includes a fixed magnet 27f extending linearly in the length direction, and a movable magnet 27m moving in the length direction of the fixed magnet 27f along the fixed magnet 27f. The fixed magnet 27f is fixed to the base 20 in a posture parallel to the X direction. The movable magnet 27m is fixed to the lower stage 23L.

As shown in FIGS. 17 and 18, the second bonding module 2b2 includes at least one linear guide 24 that linearly guides the upper stage 23u in the Y direction with respect to the lower stage 23L. FIG. 17 illustrates an example in which two linear guides 24 are provided. The two linear guides 24 are disposed on the lower stage 23L. The upper stage 23u is disposed on the two linear guides 24. The linear guide 24 includes a rail 24L extending linearly in the length direction, a slide block 24b moving in the length direction of the rail 24L along the rail 24L, and a plurality of balls interposed between the rail 24L and the slide block 24b. The rail 24 L is fixed to the lower stage 23L in a posture parallel to the Y direction. The slide block 24b is fixed to the upper stage 23u.

The actuator mechanism AC includes at least one Y actuator 25 that relatively moves the first chuck 11 and the second chuck 21 in the Y direction. FIG. 18 illustrates an example in which at least one Y actuator 25 moves the upper stage 23u in the Y direction to move the second substrate W2 held by the second chuck 21 in the Y direction. In this example, two Y actuators 25 are provided, each Y actuator 25 being a linear motor. The linear motor includes a fixed magnet 25f extending linearly in the length direction, and a movable magnet 25m moving in the length direction of the fixed magnet 25f along the fixed magnet 25f. The fixed magnet 25f is fixed to the lower stage 23L in a posture parallel to the Y direction. The movable magnet 25m is fixed to the upper stage 23u.

The X actuator 27, the Y actuator 25, and the Z actuator 18 are examples of a translation actuator that translates at least one of the first chuck 11 and the second chuck 21. The Y actuator 25 is an example of a horizontal actuator that horizontally moves at least one of the first chuck 11 and the second chuck 21. The X actuator 27 is also an example of a horizontal actuator. The Z actuator 18 is an example of a vertical actuator that vertically moves at least one of the first chuck 11 and the second chuck 21.

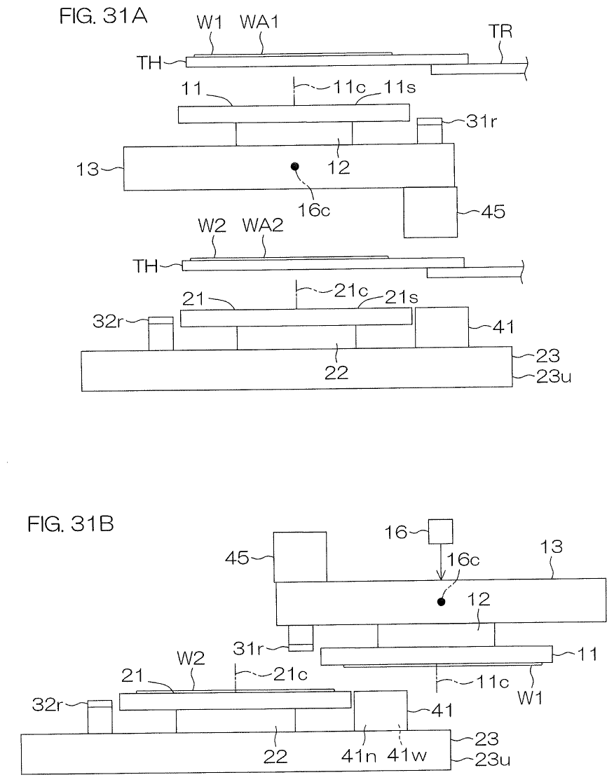

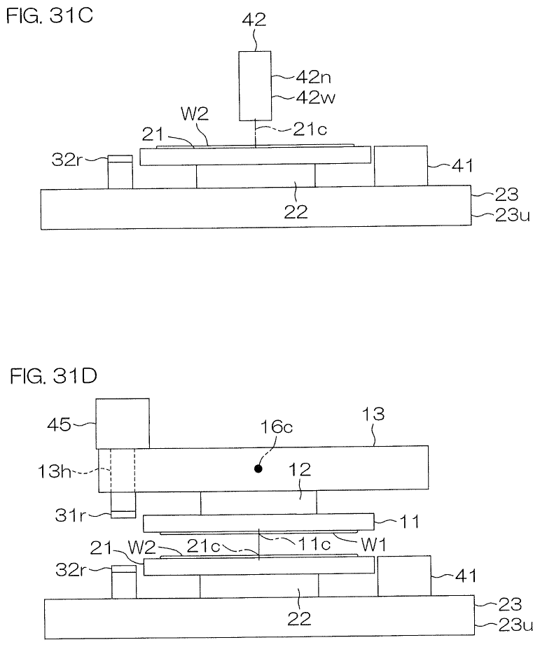

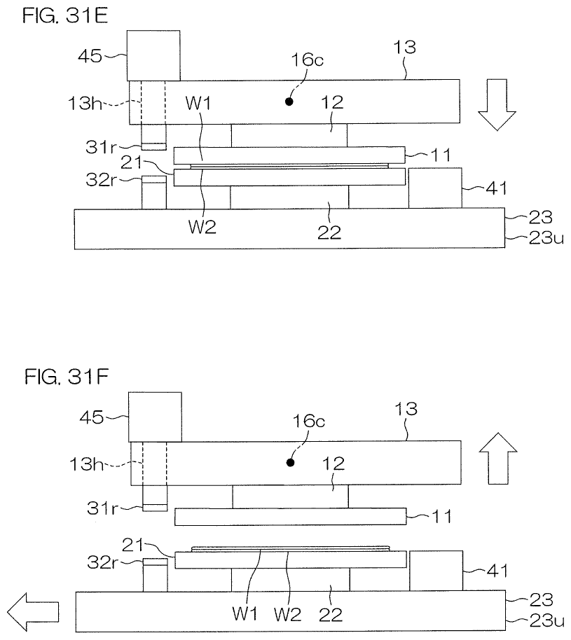

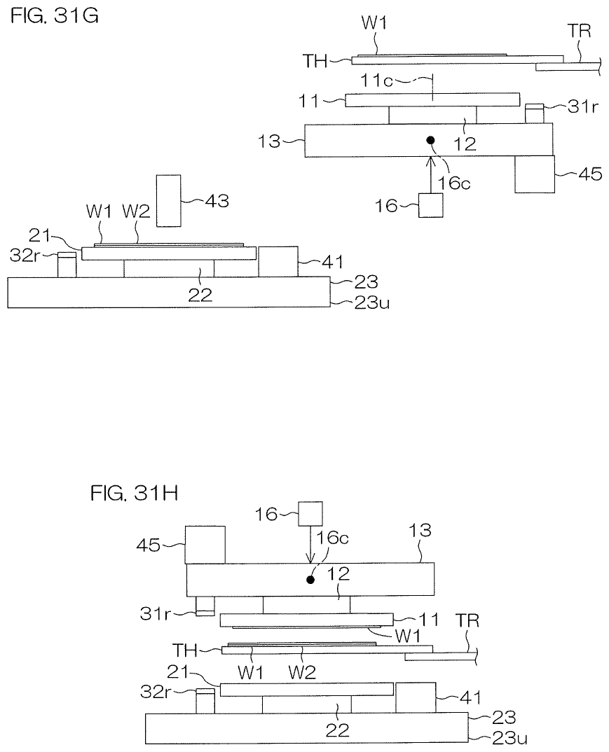

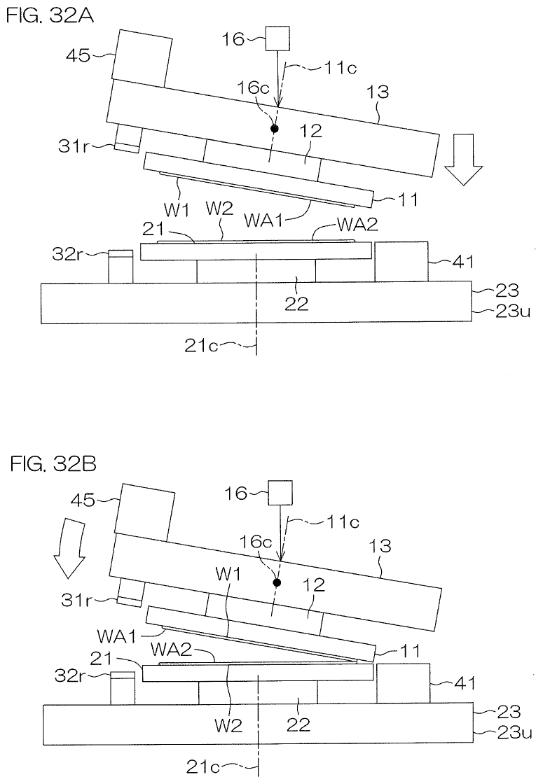

The X actuator 27 moves the second chuck 21 in the X direction with respect to the first chuck 11 between a bonding position (position shown in FIG. 31E) and a photographing position (position shown in FIG. 31G). The bonding position is a position where the first substrate W1 held by the first chuck 11 and the second substrate W2 held by the second chuck 21 are bonded. The photographing position is a position where the camera photographs the first substrate W1 and the second substrate W2 held by the second chuck 21.

The photographing position may be a range extending in at least one of the X direction and the Y direction. For example, the photographing position may include a pre-bonding photographing position where a first narrow view camera 41n and a first wide view camera 41w to be described below photograph the second substrate W2 or the like held by the second chuck 21, and a post-bonding photographing position where an inspection camera 43 to be described below photographs a first substrate W1 and a second substrate W2 held by the second chuck 21 after the first substrate W1 and the second substrate W2 are bonded.

The actuator mechanism AC includes a second rotation motor 22 that rotates the second chuck 21 with respect to the upper stage 23u around the center line 21c of the second chuck 21 corresponding to a rotation axis. The second rotation motor 22 is an electric motor. The second rotation motor 22 is disposed between the second chuck 21 and the upper stage 23u. The second rotation motor 22 is connected to the second chuck 21 and the upper stage 23u. The second substrate W2 is held by the second chuck 21 such that the center of the second substrate W2 is located on the center line 21c of the second chuck 21. When the second rotation motor 22 rotates in this state, the second substrate W2 and the second chuck 21 rotate with respect to the upper stage 23u at the same angle in the same direction as the second rotation motor 22.

As shown in FIG. 15, the second bonding module 2b2 includes a second frame 28 in which a space where the second chuck 21 and the second stage 23 can move in and out in the X direction is formed. The second frame 28 includes a pair of second side frames 28s extending upward from the upper surface of the base 20, and a second upper frame 28u extending from one second side frame 28s to the other second side frame 28s in a state of being separated upward from the base 20. FIG. 15 illustrates an example in which the second frame 28 has a gate-shaped configuration. In this example, the second upper frame 28u connects the upper ends of the pair of second side frames 28s.

The pair of second side frames 28s is fixed to the base 20. The second upper frame 28u is fixed to the pair of second side frames 28s. The pair of second side frames 28s face each other in the Y direction with a space therebetween. The second upper frame 28u faces the upper surface of the base 20 in the Z direction at an interval. The pair of second side frames 28s are disposed on both sides of the second chuck 21 and the second stage 23 in the Y direction. The second upper frame 28u is disposed above the second chuck 21 and the second stage 23 so as to overlap the second chuck 21 and the second stage 23 in a plan view.

The second frame 28 is separated from the first frame 19 in the X direction (see FIG. 7). When the X actuator 27 moves the lower stage 23L in the X direction, the second chuck 21 and the second stage 23 move into and out of the space inside the second frame 28 in the X direction. Similarly, the second chuck 21 and the second stage 23 move into and out of the space inside the first frame 19 in the X direction. The second chuck 21 and the second stage 23 can enter between the first stage 13 and the base 20. When the first chuck 11 faces downward, the second chuck 21 and the second stage 23 can enter between the first chuck 11 and the base 20.

In a state where the second chuck 21 and the second stage 23 are positioned between the pair of second side frames 28s, even if the Y actuator 25 moves the upper stage 23u in the Y direction with respect to the lower stage 23L, the second chuck 21 and the upper stage 23u do not collide with the second frame 28. Similarly, in a state where the second chuck 21 and the second stage 23 are positioned between the pair of first side frames 19s, even if the Y actuator 25 moves the upper stage 23u in the Y direction with respect to the lower stage 23L, the second chuck 21 and the upper stage 23u do not collide with the first frame 19.

The bonding unit 2b may include a plurality of distance meters that measure the distance in the vertical direction to the bonding surface WA1 of the downward first substrate W1 held by the first chuck 11. The distance meter is a non-contact type distance meter that measures a distance in a non-contact manner with an object such as the first substrate W1. The distance meter may be an optical distance meter such as a laser distance meter, or may be another distance meter.

The plurality of distance meters are disposed below the downward first substrate W1 held by the first chuck 11. The plurality of distance meters may be fixed to the upper stage 23u. In this case, the plurality of distance meters move horizontally in the same direction, speed, and movement amount as the upper stage 23u. The plurality of distance meters measure distances in the vertical direction to a plurality of positions in the bonding surface WA1 of the first substrate W1 facing downward. Thereby, the flatness of the bonding surface WA1 of the first substrate W1 can be measured.

In a case where the bonding surface WA1 of the first substrate W1 before being reversed is horizontal, when the reverse actuator 16 is strictly rotated by 180 degrees, the bonding surface WA1 of the first substrate W1 facing downward is arranged horizontally. This can be confirmed by measuring distances from the plurality of distance meters to the bonding surface WA1 of the first substrate W1 facing downward. If the bonding surface WA1 of the first substrate W1 is not horizontal, the reverse actuator 16 may be rotated until the bonding surface WA1 of the first substrate W1 is disposed horizontally. In this way, the parallel degree between the first substrate W1 and the second substrate W2 can be increased.

Next, a second reference mark 32m will be described.

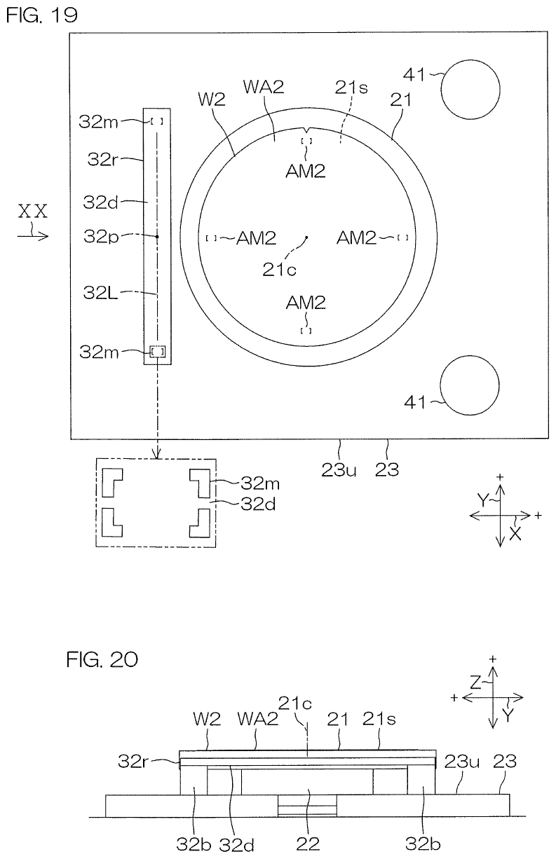

FIG. 19 is a plan view of the second stage 23. FIG. 20 is a view of the second stage 23 viewed horizontally in a direction of an arrow XX shown in FIG. 19. As shown in FIGS. 19 and 20, the second bonding module 2b2 includes a second fixed reference 32r serving as an indirect reference in aligning the second substrate W2. The second fixed reference 32r includes at least one second reference mark 32m serving as an indirect reference when the second substrate W2 is aligned, and a second display plate 32d on which at least one second reference mark 32m is marked.

FIG. 19 illustrates an example in which two second reference marks 32m having the same shape and size are provided. In this example, the second reference mark 32m has a rectangular shape (including four L-shaped figures). The second reference mark 32m may have a shape other than a rectangle. The second reference mark 32m may be formed on the second display plate 32d by photolithography, or may be formed on the second display plate 32d by another method such as laser marking.

In the example shown in FIG. 19, the second display plate 32d is a horizontal rectangular flat plate extending in the Y direction, and two second reference marks 32m having the same shape and size are marked one by one at both ends of the second display plate 32d in the Y direction. Two long sides of the second display plate 32d extend in the Y direction, and two short sides of the second display plate 32d extend in the X direction. As shown in FIG. 20, in this example, the second display plate 32d is supported by the upper stage 23u through two second support blocks 32b. An upper surface and a lower surface of the second display plate 32d are two horizontal planes parallel to each other. The lower surface of the second display plate 32d faces the horizontal and flat upper surface of the upper stage 23u in the Z direction at an interval. The lower surface of the second display plate 32d may be in contact with the upper surface of the upper stage 23u.

The at least one second reference mark 32m is used to set a second fixed point 32p and a second fixed line 32L as indirect references when the second substrate W2 is aligned. The second fixed point 32p and the second fixed line 32L are a virtual point and line. In the example shown in FIG. 19, a horizontal straight line passing through the centers of gravity of the two rectangular second reference marks 32m is set as the second fixed line 32L of the upper stage 23u. The second fixed point 32p of the upper stage 23u may be the center of gravity of one second reference mark 32m or a random point on the second fixed line 32L, or may be any of other points.

As shown in FIG. 19, the second fixed reference 32r is disposed above the upper stage 23u such that the second fixed reference 32r overlaps the upper stage 23u in a plan view. The second fixed reference 32r is fixed to the upper stage 23u. An upper end of the second fixed reference 32r is disposed below the second substrate W2 on the second chuck 21. In a state where the second substrate W2 is held by the second chuck 21, the second fixed reference 32r does not overlap the second substrate W2 held by the second chuck 21 when viewed in the direction of the center line 21c of the second chuck 21. Therefore, when the upper stage 23u is viewed in the direction of the center line 21c of the second chuck 21 in this state, not only the second reference mark 32m but also the second alignment mark AM2 of the second substrate W2 can be photographed by a camera.

As will be described below, at least one second alignment mark AM2 of the second substrate W2 held by the second chuck 21 is photographed by the camera. The camera also photographs at least one second reference mark 32m of the second fixed reference 32r. The position and angle of the second substrate W2 in the horizontal plane are specified based on the image of at least one second alignment mark AM2 photographed by the camera. The position and angle of the second fixed reference 32r in the horizontal plane are also identified based on the image of the at least one second reference mark 32m photographed by the camera. Furthermore, the relative position and angle between the second substrate W2 and the second fixed reference 32r are also specified based on the images of the second alignment mark AM2 and the second reference mark 32m. Therefore, if the position and angle of the second fixed reference 32r can be acquired, the position and angle of the second substrate W2 held by the second chuck 21 can also be acquired. These pieces of information are stored in the controller 3 (see FIG. 1).

Next, the camera provided in the bonding unit 2b will be described.

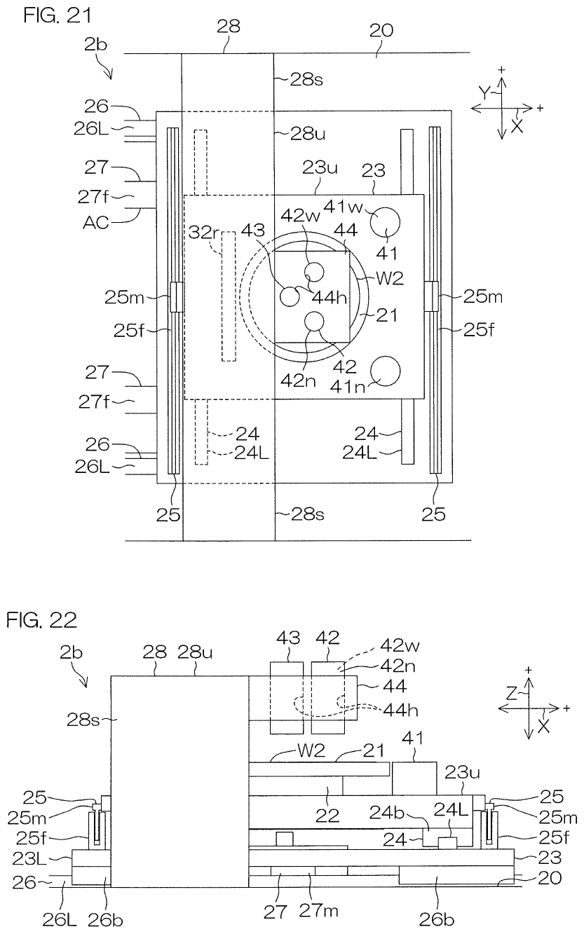

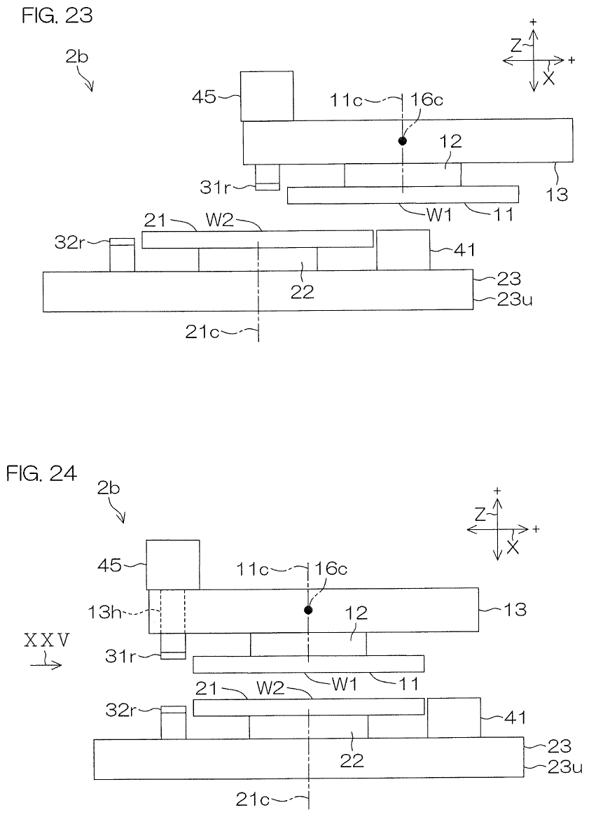

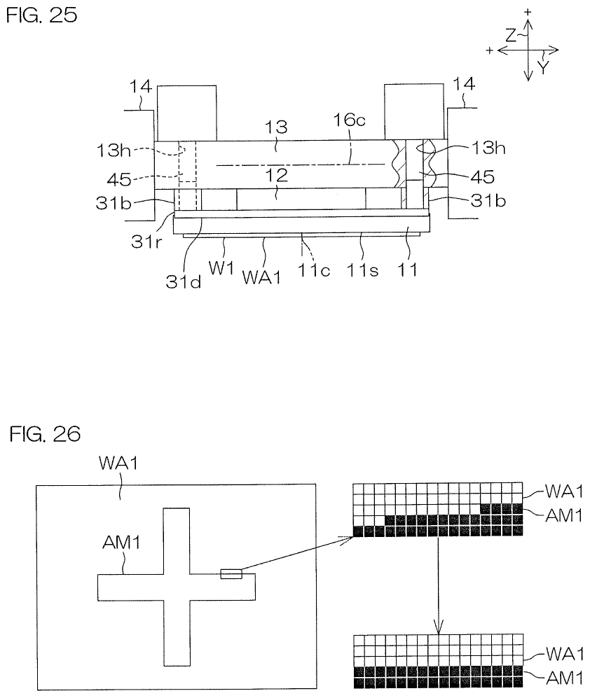

FIG. 21 is a plan view of the bonding unit 2b. FIG. 22 is a view of a second camera 42 horizontally viewed in the Y direction, which photographs the second substrate W2. FIG. 23 is a view of a first camera 41 horizontally viewed in the Y direction, which photographs the first substrate W1. FIG. 24 is a view of an alignment camera 45 that is photographing the first fixed reference 31r and the second fixed reference 32r as viewed horizontally in the Y direction. FIG. 25 is a view of the alignment camera 45 viewed horizontally in a direction of an arrow XXV shown in FIG. 24.

As shown in FIGS. 21 and 22, the bonding unit 2b includes at least one first camera 41 that photographs the first substrate W1 held by the first chuck 11 and the first fixed reference 31r, and at least one second camera 42 that photographs the second substrate W2 held by the second chuck 21 and the second fixed reference 32r. The bonding unit 2b further includes an inspection camera 43 that photographs the first substrate W1 and the second substrate W2 held by the second chuck 21 after being bonded. FIGS. 21 and 22 illustrate an example in which two first cameras 41 and two second cameras 42 are provided. The two first cameras 41 are a first narrow view camera 41n and a first wide view camera 41w. The two second cameras 42 are a second narrow view camera 42n and a second wide view camera 42w.

The first narrow view camera 41n and the first wide view camera 41w are fixed to the upper stage 23u of the second stage 23. The first narrow view camera 41n and the first wide view camera 41w move in the X direction and the Y direction at the same speed and the same amount of movement together with the upper stage 23u. The positions of the first narrow view camera 41n and the first wide view camera 41w in the X direction and the Y direction with respect to the first stage 13 are adjusted by at least one of the X actuator 27 and the Y actuator 25 moving the second stage 23.

The second narrow view camera 42n, the second wide view camera 42w, and the inspection camera 43 are fixed to the second frame 28 through a bracket 44. The second narrow view camera 42n, the second wide view camera 42w, and the inspection camera 43 are disposed above the base 20 so as to overlap the base 20 in a plan view. The inspection camera 43 is a portion of the inspection unit. The second substrate W2 is held by the second chuck 21 before being bonded to the first substrate W1, and is held by the second chuck 21 even when the bonded first substrate W1 and second substrate W2 are photographed by the inspection camera 43.

FIG. 21 illustrates an example in which the second narrow view camera 42n, the second wide view camera 42w, and the inspection camera 43 are inserted into three through holes 44h penetrating the bracket 44 in the Z direction, and are arranged on the first chuck 11 side (right side in FIG. 21) with respect to the second frame 28. The positions of the second narrow view camera 42n, the second wide view camera 42w, and the inspection camera 43 in the X direction and the Y direction with respect to the second stage 23 are adjusted by at least one of the X actuator 27 and the Y actuator 25 moving the second stage 23.

The narrow view camera is a camera having a narrower field of view than the wide view camera. The photographing range of the first narrow view camera 41n may be a portion of the photographing range of the first wide view camera 41w or may be outside the photographing range. The same applies to the second narrow view camera 42n and the second wide view camera 42w. The resolution of the narrow view camera may be equal to or different from the resolution of the wide view camera. The narrow view camera and the wide view camera include lenses of different magnifications, and may be two cameras having the same specification other than the photographing magnification such as the resolution.

The controller 3 (see FIG. 1) receives electronic data of an image of a still image or a moving image generated by the first wide view camera 41w. The controller 3 analyzes and determines the image based on the program stored in the memory 3c. The controller 3 may store the position of the first alignment mark AM1 when determining that the first alignment mark AM1 is included in the image as a result of the analysis. In this way, the photographing range of the first narrow view camera 41n can be quickly moved to the range where the first alignment mark AM1 exists. Even if the first narrow view camera 41n loses sight of the first alignment mark AM1, that is, even if the photographing range of the first narrow view camera 41n moves to the range where the first alignment mark AM1 does not exist, the photographing range of the first narrow view camera 41n can be quickly returned to the range where the first alignment mark AM1 exists.

Similarly, when determining that the first reference mark 31m is included in the image generated by the first wide view camera 41w, the controller 3 may store the position of the first reference mark 31m. Similarly, when determining that at least one of the second alignment mark AM2 and the second reference mark 32m is included in the image generated by the second wide view camera 42w, the controller 3 may store the position of at least one of the second alignment mark AM2 and the second reference mark 32m. In this way, the photographing time of the first narrow view camera 41n and the second narrow view camera 42n can be shortened.

The lenses of the first narrow view camera 41n and the first wide view camera 41w are directed upward. When the first narrow view camera 41n and the first wide view camera 41w perform photographing, as shown in FIG. 23, the first stage 13 rotates by 180 degrees around the reversing center 16c in a state where the first substrate W1 is held by the first chuck 11. The first narrow view camera 41n and the first wide view camera 41w photograph the first substrate W1 facing downward and the first fixed reference 31r facing downward. At least one of the X actuator 27 and the Y actuator 25 moves the first narrow view camera 41n and the first wide view camera 41w in at least one of the X direction and the Y direction when the first narrow view camera 41n and the first wide view camera 41w are photographing, thereby causing the first narrow view camera 41n and the first wide view camera 41w to photograph the entire range to be photographed. Thereby, the first alignment mark AM1 of the first substrate W1 and the first reference mark 31m of the first fixed reference 31r are photographed.

The lenses of the second narrow view camera 42n and the second wide view camera 42w are directed downward. When the second narrow view camera 42n and the second wide view camera 42w are photographing, as shown in FIG. 22, in a state where the second substrate W2 is held by the second chuck 21, at least one of the second substrate W2 and the second fixed reference 32r is arranged within a range that can be imaged by the second narrow view camera 42n and the second wide view camera 42w. In this state, the second narrow view camera 42n and the second wide view camera 42w photograph the second substrate W2 facing upward and the second fixed reference 32r facing upward. When the second narrow view camera 42n and the second wide view camera 42w are photographing, at least one of the X actuator 27 and the Y actuator 25 moves the second substrate W2 and the second fixed reference 32r in at least one of the X direction and the Y direction. Thereby, the second narrow view camera 42n and the second wide view camera 42w can photograph the entire range to be photographed, and the second alignment mark AM2 of the second substrate W2 and the second reference mark 32m of the second fixed reference 32r are photographed.

Similarly to the second narrow view camera 42n and the second wide view camera 42w, the lens of the inspection camera 43 is directed downward. When the inspection camera 43 photographs an image, the first substrate W1 and the second substrate W2 are arranged within a range that can be photographed by the inspection camera 43 in a state where the first substrate W1 and the second substrate W2 are held by the second chuck 21. In this state, the inspection camera 43 photographs the first substrate W1 facing downward and the second substrate W2 facing upward. At least one of the X actuator 27 and the Y actuator 25 moves the first substrate W1 and the second substrate W2 in at least one of the X direction and the Y direction while the inspection camera 43 is photographing. Thereby, the entire range to be photographed is photographed by the inspection camera 43.

The first narrow view camera 41n, the first wide view camera 41w, the second narrow view camera 42n, and the second wide view camera 42w are visible light cameras that generate electronic data of a still image or a moving image by converting visible light into an electric signal. The inspection camera 43 is an infrared camera that generates electronic data of a still image or a moving image by converting infrared rays into electric signals. The visible light camera can generate a clearer image than the infrared camera, but cannot photograph an object when there is an object that does not transmit visible light between the visible light camera and the object. Even if there is an object that does not transmit visible light between the infrared camera and the object, the infrared camera can photograph the object through the object as long as the object is made of a substance that transmits infrared light such as silicon.

When the inspection camera 43 photographs the first substrate W1 and the second substrate W2, the first substrate W1 and the second substrate W2 vertically overlap each other with the first substrate W1 facing downward and the second substrate W2 facing upward. Even when the first substrate W1 and the second substrate W2 in this state are photographed from above by the visible light camera, the first alignment mark AM1 of the first substrate W1 and the second alignment mark AM2 of the second substrate W2 are not included in the photographed image. The inspection camera 43 is an infrared camera. At least one first alignment mark AM1 of the first substrate W1 is photographed by the inspection camera 43 via the base material WD1 (see FIG. 3) of the first substrate W1. At least one second alignment mark AM2 of the second substrate W2 is photographed by the inspection camera 43 through the first substrate W1. Thereby, the first alignment mark AM1 and the second alignment mark AM2 are photographed by the inspection camera 43 in a state where the first substrate W1 and the second substrate W2 are bonded.

As shown in FIGS. 24 and 25, in addition to the first camera 41 and the like, the bonding unit 2b includes at least one alignment camera 45 that photographs the first fixed reference 31r and the second fixed reference 32r in a state where the first fixed reference 31r and the second fixed reference 32r face each other in the Z direction at intervals. FIGS. 24 and 25 show an example in which two alignment cameras 45 are provided. In FIGS. 24 and 25, the lower surface of the first stage 13 faces upward. The alignment camera 45 protrudes from the lower surface of the first stage 13. The alignment camera 45 is fixed to the first stage 13. The alignment camera 45 moves in the Z direction together with the first stage 13, and rotates around the reversing center 16c together with the first stage 13.

At least a portion of the alignment camera 45 is disposed directly below the first fixed reference 31r (disposed directly above the first fixed reference 31r in the state shown in FIGS. 24 and 25). The lens of the alignment camera 45 directly faces the first fixed reference 31r in the Z direction. FIG. 25 illustrates an example in which the alignment camera 45 is inserted into a through hole 13h penetrating the first stage 13 in the Z direction. If the alignment camera 45 and the first fixed reference 31r directly face each other in the Z direction, the arrangement and the like of the alignment camera 45 are not limited thereto. In either case, the first reference mark 31m is arranged within a range where the alignment camera 45 can photograph. The number of first reference marks 31m photographed by one alignment camera 45 may be two or more.

When alignment adjustment to minimize positional deviation between the first substrate W1 and the second substrate W2 is performed, as shown in FIGS. 24 and 25, the first stage 13 is rotated by 180 degrees around the reversing center 16c, and the first substrate W1 held by the first chuck 11 is directed downward. At this time, the first fixed reference 31r is also directed downward. When the second chuck 21 is disposed below the first chuck 11 such that the downward first substrate W1 held by the first chuck 11 and the upward second substrate W2 held by the second chuck 21 directly face each other in the Z direction, the first fixed reference 31r and the second fixed reference 32r directly face each other in the Z direction with a space therebetween. The alignment camera 45 photographs the first fixed reference 31r and the second fixed reference 32r in this state.

The alignment camera 45 is a visible light camera. When the alignment camera 45 is photographing the first fixed reference 31r and the second fixed reference 32r, the first fixed reference 31r corresponding to the mask is disposed between the alignment camera 45 and the second fixed reference 32r. The first display plate 31d of the first fixed reference 31r is a transparent plate that transmits visible light. The second display plate 32d of the second fixed reference 32r is also a transparent plate. The alignment camera 45 simultaneously photographs both the first reference mark 31m and the second reference mark 32m in a state where the first fixed reference 31r and the second fixed reference 32r directly face each other in the Z direction at an interval. If the alignment camera 45 can photograph the second reference mark 32m in this state, the second display plate 32d of the second fixed reference 32r may be a non-transparent plate that does not transmit visible light.

After the first camera 41 photographs the first alignment mark AM1 and the first reference mark 31m, not only the position and angle of the first substrate W1 in the horizontal plane but also the relative position and angle between the first substrate W1 and the first fixed reference 31r can be acquired. Similarly, after the second camera 42 photographs the second alignment mark AM2 and the second reference mark 32m, not only the position and angle of the second substrate W2 in the horizontal plane but also the relative position and angle between the second substrate W2 and the second fixed reference 32r can be acquired. When the alignment camera 45 photographs the first reference mark 31m and the second reference mark 32m, the relative position and angle between the first fixed reference 31r and the second fixed reference 32r can be acquired. Consequently, the relative position and angle between the first substrate W1 and the second substrate W2 are also indirectly acquired.

While causing the alignment camera 45 to photograph the first reference mark 31m and the second reference mark 32m, the controller 3 adjusts the relative position and angle between the first fixed reference 31r and the second fixed reference 32r so as to minimize the positional deviation of the first substrate W1 and the second substrate W2.

Specifically, the controller 3 operates one or both of the first substrate W1 and the second substrate W2 in a horizontal plane by at least one of the first rotation motor 12, the second rotation motor 22, the Y actuator 25, and the X actuator 27. Thereby, the positional deviation between the first substrate W1 and the second substrate W2 is minimized. The controller 3 monitors a change in the value of the positional deviation, determines that the alignment adjustment is completed and the alignment is completed when the value of the positional deviation converges to a certain value or less, stops the processing command for the alignment adjustment, and starts the processing command for the substrate contact step which is the next processing.

In the substrate contact step, the controller 3 lowers the first substrate W1 by the Z actuator 18 to bring the bonding surface WA1 of the first substrate W1 facing downward into contact with the bonding surface WA2 of the second substrate W2 facing upward. Thereby, the first substrate W1 and the second substrate W2 are bonded. The operation parameter such as the moving distance in the lowering operation is based on the recipe stored in the memory 3c. The controller 3 determines that the bonding completion state is established when the operation defined in the substrate contact step is completed.

After the first substrate W1 and the second substrate W2 are in the bonding completion state, the inspection camera 43 photographs the first substrate W1 and the second substrate W2 in a state where the bonded first substrate W1 and second substrate W2 are held by the second chuck 21. Thereby, the first alignment mark AM1 and the second alignment mark AM2 are photographed by the inspection camera 43 in a state where the first substrate W1 and the second substrate W2 are bonded. The deviation amount of the positions of the two bonded substrates W and the deviation amount of the angles of the two bonded substrates W are measured based on the images of the first alignment mark AM1 and the second alignment mark AM2 generated by the inspection camera 43.

The position photographed by the first camera 41 is changed by the X actuator 27 and the Y actuator 25 moving the first camera 41. The position photographed by the second camera 42 is changed by the X actuator 27 and the Y actuator 25 moving the upper stage 23u. The alignment camera 45 and the inspection camera 43 are similar to the second camera 42. The X actuator 27 and the Y actuator 25 also serve as photographing position adjustment actuators that change the position to be photographed by the camera such as the first camera 41. The bonding unit 2b may include a photographing position adjustment actuator that moves the second camera 42 and the inspection camera 43 with respect to the base 20.

FIG. 26 is a schematic view showing one example of an image of a cross-shaped first alignment mark AM1 generated by the first camera 41.

The first camera 41 generates a rectangular or square two-dimensional image including a plurality of pixels aligned in a longitudinal direction and a lateral direction orthogonal to each other. The controller 3 receives electronic data of an image of a still image or a moving image generated by the first camera 41. The controller 3 analyzes and determines the image based on the program stored in the memory 3c. The same applies to other cameras such as the second camera 42.

In a case where the first reference mark 31m has a shape that can specify the height direction and the width direction orthogonal to each other, when the first camera 41 photographs the first reference mark 31m, the height direction and the width direction of the first reference mark 31m are specified based on the image of the first reference mark 31m. Thereby, the inclination angle (for example, the inclination angle of the first reference mark 31m in the width direction with respect to the lateral direction of the image) of the first reference mark 31m with respect to the image generated by the first camera 41 can be acquired.

The height direction and the width direction of the first reference mark 31m are recorded in the memory 3c in association with the shape of the first reference mark 31m to be used. The controller 3 specifies the height direction and the width direction of the first reference mark 31m in the imaged image by matching the shape of the first reference mark 31m recorded in the memory 3c with the first reference mark 31m in the image generated by the first camera 41.

When the first reference mark 31m has a shape that can specify the height direction and the width direction orthogonal to each other, the first fixed reference 31r may be arranged such that the inclination angle of the first reference mark 31m with respect to the longitudinal direction or the lateral direction of the image generated by the first camera 41 is equal to or less than an upper limit value. For example, when a lateral line parallel to the width direction is included in the contour line of the first reference mark 31m, the first fixed reference 31r may be arranged such that the inclination angle of the lateral line with respect to the lateral direction of the image generated by the first camera 41 is equal to or less than the upper limit value. The same applies to the arrangement of the second fixed reference 32r with respect to the second reference mark 32m.

Similarly to the first reference mark 31m, in a case where the first alignment mark AM1 has a shape in which the height direction and the width direction orthogonal to each other can be specified, when the first camera 41 photographs the first alignment mark AM1, the height direction and the width direction of the first alignment mark AM1 are specified based on the image of the first alignment mark AM1. Thereby, the inclination angle (for example, the inclination angle of the first alignment mark AM1 in the width direction with respect to the lateral direction of the image) of the first alignment mark AM1 with respect to the image generated by the first camera 41 can be acquired.

When the first alignment mark AM1 has a shape that can specify the height direction and the width direction orthogonal to each other, the controller 3 may determine whether or not the inclination angle of the first alignment mark AM1 with respect to the longitudinal direction or the lateral direction of the image generated by the first camera 41 exceeds the upper limit value. When determining that the inclination angle of the first alignment mark AM1 exceeds the upper limit value, the controller 3 may cause the first rotation motor 12 to rotate the first chuck 11 such that the inclination angle decreases to the upper limit value or less, and then cause the first camera 41 to photograph the first alignment mark AM1.

The left side of FIG. 26 illustrates an example of an image generated by the first camera 41. The two grids on the right side of FIG. 26 are obtained by enlarging a portion of the image on the left side of FIG. 26. Each square block in each lattice corresponds to a pixel. The boundary between the black block and the white block corresponds to the contour line of the first alignment mark AM1. In the upper right grid of FIG. 26, the contour line of the first alignment mark AM1 is inclined with respect to the lateral direction of the image (the lateral direction of the paper surface). On the other hand, in the lower right grid of FIG. 26, the contour line of the first alignment mark AM1 is parallel to the lateral direction of the image.

For example, the controller 3 may cause the first rotation motor 12 to rotate the first chuck 11 such that the image generated by the first camera 41 changes from the state of the upper right grid in FIG. 26 to the state of the lower right grid in FIG. 26. In this way, the shape of the first alignment mark AM1 can be specified with higher accuracy from the image generated by the first camera 41, and the position and angle of the first substrate W1 can be specified with higher accuracy. The same applies to the case where the second camera 42 photographs the second alignment mark AM2 and the case where the inspection camera 43 photographs the first alignment mark AM1 and the second alignment mark AM2.

Next, a displacement detector 46 will be described.

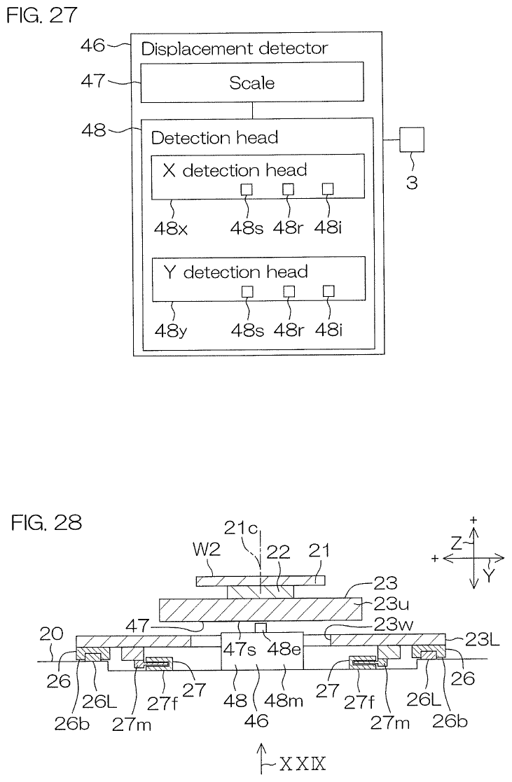

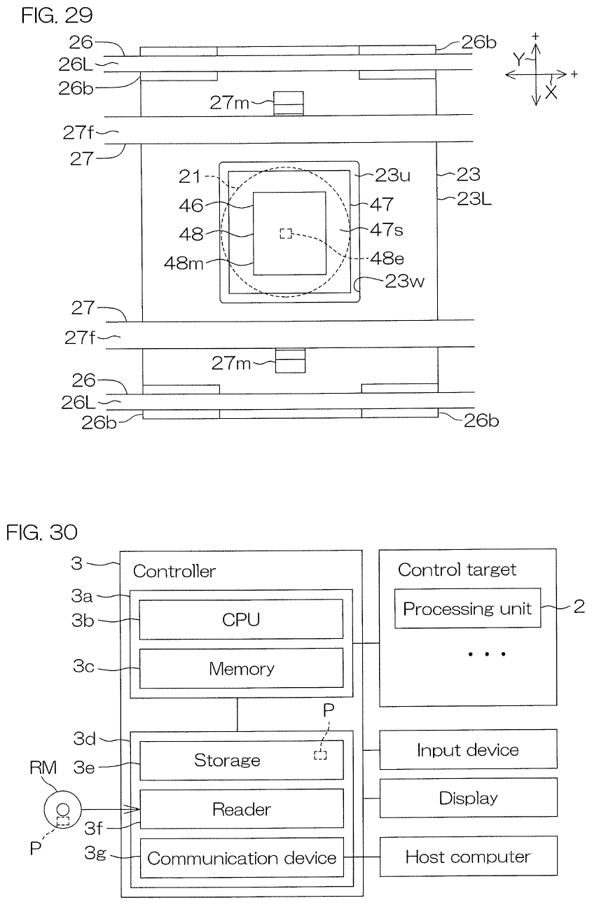

FIG. 27 is a block diagram of the displacement detector 46. FIG. 28 is a view showing a vertical cross-section of the displacement detector 46. FIG. 29 is a view of the displacement detector 46 viewed vertically in a direction of an arrow XXIX shown in FIG. 28.

As shown in FIG. 27, the bonding unit 2b includes the displacement detector 46 that detects the relative displacement between the base 20 and the second chuck 21 in the horizontal direction. FIGS. 28 and 29 illustrate an example in which the displacement detector 46 detects the relative displacement between the base 20 and the second chuck 21 in the horizontal direction by detecting the displacement of the second chuck 21 in the X direction and the Y direction with respect to the base 20.

The displacement detector 46 includes an X displacement detector that detects relative displacement between the base 20 and the second chuck 21 in the X direction, and a Y displacement detector that detects relative displacement between the base 20 and the second chuck 21 in the Y direction. The Y displacement detector may be integrated with the X displacement detector or may be a displacement detector independent of the X displacement detector. FIG. 27 shows an example of the former.

The X displacement detector may be an optical displacement detector or a displacement detector of another type such as a magnetic type. In the former case, the displacement detector may be a lattice interference linear encoder or another type of displacement detector such as an interferometer. Compared to an interferometer such as a laser interferometer, a grid interference linear encoder is hardly affected by a change in environment such as a change in temperature or a change in humidity, and can stably detect displacement. The X displacement detector may be an absolute position detector that detects an absolute position of an object such as the second substrate W2 or a relative position detector that detects a relative position of the object. The same applies to the Y displacement detector. If the Y displacement detector is independent of the X displacement detector, the Y displacement detector may be a different form of displacement detector than the X displacement detector.

FIG. 27 illustrates an example in which the displacement detector 46 includes a lattice interference linear encoder that detects the displacement of the second substrate W2 in the X direction and the Y direction. The displacement detector 46 of the lattice interference type includes a scale 47 that moves in the X direction and the Y direction together with an object such as the second chuck 21, and a detection head 48 that detects displacement of the scale 47 in the X direction and the Y direction. The detection head 48 is a non-contact displacement meter that detects displacement of the scale 47 in the X direction and the Y direction without contacting the scale 47.

The detection head 48 includes an X detection head 48x that detects displacement of the scale 47 in the Y direction and a Y detection head 48y that detects displacement of the scale 47 in the Y direction. Each of the X detection head 48x and the Y detection head 48y includes a light source 48s that emits light reflected by the scale 47, a light receiving element 48r that converts the light reflected by the scale 47 into an electric signal, and an interpolator 48i that calculates a moving amount and a moving direction of the scale 47 in the horizontal direction based on the electric signal input from the light receiving element 48r. The displacement of the second substrate W2 detected by the displacement detector 46 is input to the controller 3 through the interpolator 48i.

The scale 47 is a reflection type diffraction grating that reflects light emitted from a light source 48s such as a semiconductor laser. The scale 47 may be a holographic diffraction grating or other form of diffraction grating, such as a blazed diffraction grating. The scale 47 may be a flat diffraction grating or a volume diffraction grating. FIG. 29 illustrates an example in which the scale 47 is a 2D scale (two-dimensional scale) that reflects light emitted from the X detection head 48x and light emitted from the Y detection head 48y. In this example, the scale 47 includes a square reflective surface 47s that reflects light emitted by the light source 48s.

The 2D scale includes an X diffraction grating including an uneven surface in which protrusion portions protruding in the Z direction and recess portions recessed in the Z direction are regularly and alternately arranged in the X direction, and a Y diffraction grating including an uneven surface in which protrusion portions protruding in the Z direction and recess portions recessed in the Z direction are regularly and alternately arranged in the Y direction. The Y diffraction grating horizontally moves in the same direction, speed, and amount of movement as the X diffraction grating. The tip of the protrusion of the X diffraction grating and the tip of the protrusion portion of the Y diffraction grating are arranged on one horizontal plane. The uneven surface of the X diffraction grating and the uneven surface of the Y diffraction grating are a portion of the reflective surface 47s of the scale 47. The light emitted from the light source 48s is reflected by the uneven surface of the X diffraction grating or the uneven surface of the Y diffraction grating.

The recess portion of the X diffraction grating may be a continuous groove extending in the Y direction whose length is longer than the width or a plurality of holes arranged in the Y direction, or may include a groove and a plurality of holes. The recess portion of the Y diffraction grating may be a continuous groove extending in the X direction whose length is longer than the width or a plurality of holes arranged in the X direction, or may include a groove and a plurality of holes. A vertical cross-section of the protrusion portion and the recess portion of the X diffraction grating may be any of an arc, a square, and a rectangle, or may be other than these. The same applies to the vertical cross-sections of the protrusion portion and the recess portion of the Y diffraction grating.

The scale 47 is fixed to the lower surface of the upper stage 23u with the reflective surface 47s that reflects light facing downward. When the upper stage 23u moves in the Y direction with respect to the base 20, the scale 47 horizontally moves in the same direction, speed, and movement amount as those of the upper stage 23u. When the lower stage 23L moves in the X direction with respect to the base 20, the scale 47 horizontally moves in the same direction, speed, and movement amount as those of the lower stage 23L. When the second substrate W2 held by the second chuck 21 horizontally moves in at least one of the X direction and the Y direction with respect to the base 20, the scale 47 horizontally moves in the same direction, speed, and movement amount as those of the second substrate W2. Even when the upper stage 23u moves in the Y direction with respect to the lower stage 23L, the scale 47 does not collide with the lower stage 23L.

The detection head 48 is disposed below the scale 47 and the upper stage 23u. The detection head 48 directly faces the scale 47 in the Z direction. The detection head 48 is inserted into a through window 23w vertically penetrating the lower stage 23L. The detection head 48 is fixed to the base 20. The detection head 48 includes a light emitting portion 48e directly facing the scale 47 in the Z direction, and a main body 48m that supports the light emitting portion 48e. The main body 48m is inserted into the through window 23w of the lower stage 23L. The light emitting portion 48e is disposed above the upper surface of the lower stage 23L. Even when the second chuck 21 is located at any position, the detection head 48 does not contact the lower stage 23L.

When the second chuck 21 is located at any position, the light emitting portion 48e directly faces the scale 47 in the Z direction. The light of the light source 48s (see FIG. 27) travels from the light emitting portion 48e to the scale 47, is reflected by the scale 47, and then enters the detection head 48 from the light emitting portion 48e. The detection head 48 detects displacement of the scale 47 in the X direction and the Y direction with respect to the base 20. Thereby, displacement of the second chuck 21 in the X direction and the Y direction with respect to the base 20 is detected. The detection results of the displacement in the X direction and the Y direction are transmitted to the controller 3.

Next, an electrical arrangement of the substrate bonding apparatus 1 will be described.

FIG. 30 is a block diagram showing the electrical arrangement of the substrate bonding apparatus 1. The controller 3 controls electrical devices and electronic devices provided in the substrate bonding apparatus 1 by sending control signals. Also, the controller 3 receives signals from various cameras or detectors, etc. provided in the substrate bonding apparatus 1 and performs storing signals or processing signals. The controller 3 is programmed to carry out each of steps described below.

The controller 3 includes at least one computer. The computer includes a computer main body 3a and a peripheral device 3d that is connected to the computer main body 3a. The computer main body 3a includes a CPU 3b (central processing unit) that executes various types of commands and a memory 3c that stores information. The peripheral device 3d includes a storage 3e that stores information to be sent to and received from the memory 3c such as a program P, a reader 3f that reads information from a removable medium RM and a communication device 3g that communicates with other devices such as a host computer.

The controller 3 is connected to an input device and a display. The input device is operated when an operator such as a user or a maintenance operator inputs information to the substrate bonding apparatus 1. The information is displayed on the screen of the display. The input device may be any one of a keyboard, a pointing device and a touch panel or may be a device other than those. A touch panel display that serves both as the input device and the display may be provided in the substrate bonding apparatus 1.

The CPU 3b executes the program P stored in the storage 3e. £ The program P within the storage 3e may be previously installed in the controller 3, may be fed through the reader 3f from the removable medium RM to the storage 3e or may be fed from an external device such as the host computer to the storage 3e through the communication device 3g.

The memory 3c is a volatile memory that retains memory only when power is supplied. The storage 3e and the removable medium RM are non-volatile memories that retain memory even when power is not supplied. The storage 3e is, for example, a magnetic storage device such as a hard disk drive. The removable medium RM is, for example, an optical disc such as a compact disc or a semiconductor memory such as a memory card. The removable medium RM is an example of a computer readable recording medium in which the program P is recorded. The removable medium RM is a non-transitory tangible recording medium (non-transitory tangible medium).

Next, a first example of bonding of the first substrate W1 and the second substrate W2 will be described.

FIGS. 31A, 31B, 31C, 31D, 31E, 31F, 31G, and 31H are schematic views for illustrating a first example of bonding of the first substrate W1 and the second substrate W2 performed by the bonding unit 2b. FIGS. 31A to 31H illustrate the first chuck 11, the second chuck 21, and the like when viewed horizontally in the Y direction. The same applies to FIGS. 32A and 32B.

When the first substrate W1 and the second substrate W2 are bonded by the bonding unit 2b, as shown in FIG. 31A, the transfer robot TR arranges the first substrate W1 in the space above the first chuck 11 in the loading/unloading state while horizontally holding the first substrate W1 with the bonding surface WA1 facing upward by the hand TH. Similarly, the transfer robot TR disposes the second substrate W2 in the space above the second chuck 21 in the loading/unloading state while horizontally holding the second substrate W2 with the bonding surface WA2 facing upward by the hand TH.

The loading/unloading state of the first chuck 11 is a state in which the first chuck 11 is maintained at a position and a posture in which the first substrate W1 can be moved between the transfer robot TR and the first chuck 11, the rotation angle of the first chuck 11 is 0, and the center line 11c of the first chuck 11 is vertical. The loading/unloading state of the second chuck 21 is a state in which the second chuck 21 is maintained at a position and a posture in which the second substrate W2 can be moved between the transfer robot TR and the second chuck 21, and the rotation angle of the second chuck 21 is 0.

The transfer robot TR may place the first substrate W1 on the first chuck 11 in the loading/unloading state, or may place the first substrate W1 on a plurality of ascending/descending pins that move up and down while horizontally supporting the first substrate W1 between a lower position where the first substrate W1 is placed on the first chuck 11 and an upper position where the first substrate W1 is separated upward from the first chuck 11. The same applies to the second substrate W2. In either case, the first substrate W1 is placed on the first chuck 11 in the loading/unloading state with the bonding surface WA1 facing upward, and is sucked to the first chuck 11. Similarly, the second substrate W2 is placed on the second chuck 21 in the loading/unloading state with the bonding surface WA2 facing upward, and is sucked to the second chuck 21.

When the first suction surface 11s of the first chuck 11 in the loading/unloading state is a horizontal plane, the upper surface (bonding surface WA1) and the lower surface of the first substrate W1 are maintained in a horizontal plane even after the first substrate W1 is sucked to the first chuck 11. In a case where the first suction surface 11s of the first chuck 11 in the loading/unloading state has a shape other than the horizontal plane, when the first substrate W1 is sucked to the first chuck 11, the upper surface and the lower surface of the first substrate W1 are elastically deformed from the horizontal plane into the same or substantially the same shape as the first suction surface 11s of the first chuck 11, and are maintained in the same shape. The same applies to the shapes of the upper surface and the lower surface of the second substrate W2.

FIG. 31A illustrates an example in which the first suction surface 11s of the first chuck 11 in the loading/unloading state is a horizontal plane, and the second suction surface 21s of the second chuck 21 in the loading/unloading state is a horizontal plane. Therefore, in this example, even after the first substrate W1 is sucked to the first chuck 11, the upper surface and the lower surface of the first substrate W1 are maintained in a horizontal plane. Similarly, even after the second substrate W2 is sucked to the second chuck 21, the upper surface and the lower surface of the second substrate W2 are maintained in a horizontal plane.

The first substrate W1 may be placed on the first chuck 11 before or after the second substrate W2 is placed on the second chuck 21, or may be placed on the first chuck 11 at the same time as the second substrate W2 is placed on the second chuck 21. A hand TH that transfers the first substrate W1 may be the same as or different from the hand TH that transfers the second substrate W2. In the latter case, the two hands TH of one transfer robot TR may transfer the first substrate W1 and the second substrate W2, or the two transfer robots TR may transfer the first substrate W1 and the second substrate W2.

When the first substrate W1 is placed on the first chuck 11, as shown in FIG. 31B, the reverse actuator 16 rotates the first chuck 11 by 180 degrees to face the bonding surface WAI of the first substrate W1 downward. Before or after that, the upper stage 23u is arranged in a photographing region where the first narrow view camera 41n and the first wide view camera 41w attached to the upper stage 23u can photograph at least one of the first substrate W1 and the first fixed reference 31r. In this state, the first narrow view camera 41n and the first wide view camera 41w start photographing. If necessary, the first narrow view camera 41n and the first wide view camera 41w may be moved horizontally with respect to the first substrate W1 during photographing.

The first narrow view camera 41n and the first wide view camera 41w photograph at least one first alignment mark AM1 of the first substrate W1 and at least one first reference mark 31m of the first fixed reference 31r. After that, the first narrow view camera 41n and the first wide view camera 41w finish photographing. By analyzing the image of the at least one photographed first alignment mark AM1, the position and angle of the first substrate W1 are grasped. Similarly, the position and angle of the first fixed reference 31r are grasped by analyzing the image of at least one photographed first reference mark 31m. Thereby, the position and angle of the first substrate W1 with respect to the first fixed reference 31r are grasped.

For example, the coordinate position of the first narrow view camera 41n when the first alignment mark AM1 is imaged may be calculated based on the design information of the device and the output of the displacement detector 46 to be described below, and the coordinate position of the first alignment mark AM1 may be specified based on the calculated coordinate position of the first narrow view camera 41n and the position of the first alignment mark AM1 in the imaged image. By specifying the coordinate position of the first reference mark 31m by a similar method, the relative positions of the first alignment mark AM1 and the first reference mark 31m may be calculated, and the position of the first substrate W1 with respect to the first fixed reference 31r may be grasped.

When the second substrate W2 is placed on the second chuck 21, as shown in FIG. 31C, the upper stage 23u is arranged in a photographing region where the second narrow view camera 42n and the second wide view camera 42w can photograph at least one of the second substrate W2 and the second fixed reference 32r. In this state, the second narrow view camera 42n and the second wide view camera 42w start photographing. If necessary, the upper stage 23u may be moved horizontally with respect to the second narrow view camera 42n and the second wide view camera 42w during photographing.

The second narrow view camera 42n and the second wide view camera 42w photograph at least one second alignment mark AM2 of the second substrate W2 and at least one second reference mark 32m of the second fixed reference 32r. After that, the second narrow view camera 42n and the second wide view camera 42w finish photographing. By analyzing the image of the at least one photographed second alignment mark AM2, the position and angle of the second substrate W2 are grasped. Similarly, the position and angle of the second fixed reference 32r are grasped by analyzing the image of at least one photographed second reference mark 32m. Thereby, the position and angle of the second substrate W2 with respect to the second fixed reference 32r are grasped.

For example, the position of the second chuck 21 when the second alignment mark AM2 is imaged may be acquired based on the output of the displacement detector 46 to be described below, and the coordinate position of the second alignment mark AM2 associated with the position of the second chuck 21 may be specified based on the position of the second alignment mark AM2 in the imaged image. The position of the second reference mark 32m is also specified in association with the position of the second chuck 21 by a similar method. The relative position between the second alignment mark AM2 and the second reference mark 32m can be calculated by calculating the coordinate position of the second alignment mark AM2 when the second reference mark 32m is imaged based on the position of the second chuck 21 when the second reference mark 32m is imaged and the position of the second chuck 21 when the second alignment mark AM2 is imaged. Thereby, the position of the second substrate W2 with respect to the second fixed reference 32r may be grasped.

At least a portion of the period in which the second narrow view camera 42n and the second wide view camera 42w photograph the second substrate W2 and the second fixed reference 32r may or may not be the same as the period in which the first narrow view camera 41n and the first wide view camera 41w photograph the first substrate W1 and the first fixed reference 31r. At least a portion of the period in which the second alignment mark AM2 of the second substrate W2 held by the second chuck 21 is photographed may be or may not be the same as the period in which the second reference mark 32m is photographed. The same applies to the period in which the first alignment mark AM1 and the first reference mark 31m are photographed.

After grasping the position and angle of the first substrate W1 with respect to the first fixed reference 31r and the position and angle of the second substrate W2 with respect to the second fixed reference 32r, the controller 3 operates the actuator mechanism AC to change the first substrate W1 and the second substrate W2 from the non-facing state to the facing state. Thereafter, the controller 3 operates the actuator mechanism AC to change the first substrate W1 and the second substrate W2 from the facing state to the alignment completion state. Thereafter, the controller 3 operates the actuator mechanism AC to change the first substrate W1 and the second substrate W2 from the alignment completion state to the bonding completion state.

The non-facing state is a state in which the first substrate W1 and the second substrate W2 do not overlap when the first substrate W1 and the second substrate W2 are viewed vertically. The facing state and the alignment completion state are states in which the first substrate W1 and the second substrate W2 face each other vertically in a state in which the entire bonding surface WA1 of the first substrate W1 and the entire bonding surface WA2 of the second substrate W2 are separated from each other. The facing state is a state before alignment of the first substrate W1 and the second substrate W2 is performed, and the alignment completion state is a state after alignment of the first substrate W1 and the second substrate W2 is performed. The facing state is a non-alignment state. The bonding completion state is a state in which the entire bonding surface WA1 of the first substrate W1 and the entire bonding surface WA2 of the second substrate W2 are in contact with each other.

When the first substrate W1 and the second substrate W2 are changed from the non-facing state to the facing state, the upper stage 23u and the lower stage 23L are moved in the X direction in a state where the bonding surface WA1 of the first substrate W1 held by the first chuck 11 faces downward, so that the second substrate W2 held by the second chuck 21 is moved in the X direction with respect to the first substrate W1 held by the first chuck 11. Thereby, as shown in FIG. 31D, the first substrate W1 and the second substrate W2 face each other vertically in a state where the entire bonding surface WA1 of the first substrate W1 and the entire bonding surface WA2 of the second substrate W2 are separated from each other.

After the first substrate W1 and the second substrate W2 are changed to the facing state, the first substrate W1 and the second substrate W2 are relatively moved in at least one of the X direction, the Y direction, the first θ direction (the circumferential direction of the first substrate W1), and the second @ direction (the circumferential direction of the second substrate W2) in a state where the bonding surface WA1 of the first substrate W1 held by the first chuck 11 faces downward. Thereby, the first substrate W1 and the second substrate W2 change from the facing state to the alignment completion state. Thereafter, by moving the first stage 13 in the Z direction, the first substrate W1 held by the first chuck 11 is lowered with respect to the second substrate W2 held by the second chuck 21. Thereby, as shown in FIG. 31E, the entire bonding surface WA1 of the first substrate W1 contacts the entire bonding surface WA2 of the second substrate W2, and the first substrate W1 and the second substrate W2 change from the alignment completion state to the bonding completion state.

The bonding completion state is a state in which the first substrate W1 and the second substrate W2 are aligned with reference to at least one first alignment mark AM1 and at least one second alignment mark AM2. The alignment completion state may be different from the bonding completion state only in whether or not the first substrate W1 and the second substrate W2 are separated from each other. That is, the alignment completion state may be a state in which the positional deviation between the first substrate W1 and the second substrate W2 is minimized in a state in which the first substrate W1 and the second substrate W2 are separated from each other.

As shown in FIG. 31D, the facing state of the first substrate W1 and the second substrate W2 is a state in which the first fixed reference 31r and the second fixed reference 32r overlap each other when the first fixed reference 31r and the second fixed reference 32r are viewed vertically. Before or after the first substrate W1 and the second substrate W2 are faced to each other, the alignment camera 45 attached to the first stage 13 starts photographing. Thereby, the first fixed reference 31r and the second fixed reference 32r are photographed by the alignment camera 45 in a state of overlapping each other in a plan view.

The controller 3 grasps the position and angle of the first fixed reference 31r by analyzing the image of the first fixed reference 31r photographed by the alignment camera 45. Similarly, the controller 3 grasps the position and angle of the second fixed reference 32r by analyzing the image of the second fixed reference 32r photographed by the alignment camera 45. Since the first narrow view camera 41n and the first wide view camera 41w have already photographed the first substrate W1 and the first fixed reference 31r, the position and angle of the first substrate W1 can be indirectly grasped from the position and angle of the first fixed reference 31r. Similarly, since the second narrow view camera 42n and the second wide view camera 42w have already photographed the second substrate W2 and the second fixed reference 32r, the position and angle of the second substrate W2 can be indirectly grasped from the position and angle of the second fixed reference 32r. Therefore, the first substrate W1 and the second substrate W2 can be indirectly aligned by adjusting the relative position and angle between the first fixed reference 31r and the second fixed reference 32r.

The controller 3 relatively moves the first substrate W1 and the second substrate W2 in at least one of the X direction, the Y direction, the first e direction, and the second θ direction while causing the alignment camera 45 to photograph the first fixed reference 31r and the second fixed reference 32r. Thereby, the first substrate W1 and the second substrate W2 are aligned in a state of being separated from each other, and the state changes to an alignment completion state. After the controller 3 determines that the first substrate W1 and the second substrate W2 have changed to the alignment completion state, the alignment camera 45 finishes photographing.

After the first substrate W1 and the second substrate W2 are changed to the alignment completion state, the controller 3 relatively moves the first substrate W1 and the second substrate W2 at least in the Z direction to bring the entire bonding surface WA1 of the first substrate W1 into contact with the entire bonding surface WA2 of the second substrate W2. Thereby, the first substrate W1 and the second substrate W2 change from the alignment completion state to the bonding completion state. When the first substrate W1 and the second substrate W2 change to the bonding completion state, the first chuck 11 releases the holding of the first substrate W1, and the second chuck 21 continues the holding of the second substrate W2. Therefore, the bonded first substrate W1 and the second substrate W2 are held by the second chuck 21.

After the first substrate W1 and the second substrate W2 change to the bonding completion state, the controller 3 raises the first chuck 11 and retracts the second chuck 21 (moves to the minus side in the X direction) as shown in FIG. 31F. After the first chuck 11 is raised, as shown in FIG. 31G, the reverse actuator 16 rotates the first chuck 11 such that the center line 11c of the first chuck 11 is vertical, and directs the first chuck 11 upward. If necessary, the first rotation motor 12 rotates the first chuck 11 to return the rotation angle of the first chuck 11 to 0. Thereby, the first chuck 11 returns to the loading/unloading state. The reverse actuator 16 may start the rotation of the first chuck 11 before or after the second chuck 21 retreats, or may start the rotation of the first chuck 11 simultaneously with the retreating of the second chuck 21. The same applies to the first rotation motor 12.

After the first substrate W1 and the second substrate W2 are changed to the bonding completion state, as shown in FIG. 31G, the upper stage 23u is arranged in a photographing region where the inspection camera 43 can photograph the first substrate W1 and the second substrate W2 on the second chuck 21. Before or after that, the inspection camera 43 starts photographing. Thereby, at least one first alignment mark AM1 and at least one second alignment mark AM2 are photographed in a state where the first substrate W1 and the second substrate W2 are bonded. If necessary, the upper stage 23u may be moved horizontally with respect to the inspection camera 43 during the photographing.

Images of the first alignment mark AM1 and the second alignment mark AM2 photographed by the inspection camera 43 are transmitted to the controller 3 and analyzed. Through the analysis, the bonding accuracy between the first substrate W1 and the second substrate W2 is detected. Further, based on the detected bonding accuracy of the first substrate W1 and the second substrate W2, a change in alignment of the first substrate W1 and the second substrate W2 between the alignment completion state and the bonding completion state is detected. When another first substrate W1 and another second substrate W2 are bonded, the alignment of the first substrate W1 and the second substrate W2 in the alignment completion state is corrected on the basis of the detected change in alignment. Thereby, the subsequent first substrate W1 and the second substrate W2 are bonded with higher precision.

After the first substrate W1 and the second substrate W2 on the second chuck 21 are photographed by the inspection camera 43, the second chuck 21 is moved in the X direction until the second chuck 21 returns to the loading/unloading state while the bonded first substrate W1 and second substrate W2 are held by the second chuck 21. If necessary, the second rotation motor 22 rotates the second chuck 21 to return the rotation angle of the second chuck 21 to 0. Thereafter, as shown in FIG. 31H, the second chuck 21 releases the holding of the second substrate W2, and the hand TH of the transfer robot TR directly or indirectly receives the first substrate W1 and the second substrate W2 from the second chuck 21. Thereby, the bonded first substrate W1 and second substrate W2 are horizontally held by the hand TH of the transfer robot TR, and are transferred to the next destination.

When the next first substrate W1 and second substrate W2 are bonded, the above-described series of steps is performed again. The next first substrate W1 may be placed on the first chuck 11 before or after the immediately preceding first substrate W1 and second substrate W2 are unloaded from the second chuck 21, or may be placed on the first chuck 11 simultaneously with the immediately preceding first substrate W1 and second substrate W2 being unloaded from the second chuck 21. For example, as shown in FIG. 31G, the next first substrate W1 may be placed on the first chuck 11 when the inspection camera 43 is photographing the bonded first substrate W1 and second substrate W2. In this case, as shown in FIG. 31H, the reverse actuator 16 may reverse the next first substrate W1 before carrying out the immediately preceding first substrate W1 and second substrate W2 from the second chuck 21.

Next, a second example of bonding of the first substrate W1 and the second substrate W2 will be described.

FIGS. 32A and 32B are schematic views for illustrating the second example of bonding of the first substrate W1 and the second substrate W2 performed by the bonding unit 2b.

As described above, the first substrate W1 and the second substrate W2 change from the non-facing state to the bonding completion state through the facing state and the alignment completion state. The bonding completion state is a state in which the entire bonding surface WA1 of the first substrate W1 and the entire bonding surface WA2 of the second substrate W2 are in contact with each other. The alignment completion state may be a state in which the entire bonding surface WA1 of the first substrate W1 and the entire bonding surface WA2 of the second substrate W2 are parallel or non-parallel, or a portion of the bonding surface WA1 of the first substrate W1 and a portion of the bonding surface WA2 of the second substrate W2 may be parallel, and the remaining portion of the bonding surface WA1 of the first substrate W1 and the remaining portion of the bonding surface WA2 of the second substrate W2 may be non-parallel.

That is, in the alignment completion state, in addition to whether or not the first substrate W1 and the second substrate W2 are separated from each other (in addition to the position of the first substrate W1 in the vertical direction with respect to the second substrate W2), at least one of the position of the first substrate W1 in the horizontal direction with respect to the second substrate W2, the posture of the first substrate W1 with respect to the second substrate W2, the relative angle between the first substrate W1 and the second substrate W2 around the vertical straight line, the shape of the bonding surface WA1 of the first substrate W1, and the shape of the bonding surface WA2 of the second substrate W2 may be different from the bonding completion state.

FIGS. 31A to 31H illustrate an example in which the first substrate W1 and the second substrate W2 are bonded by entire surface simultaneous bonding in which the entire bonding surface WA1 of the first substrate W1 and the entire bonding surface WA2 of the second substrate W2 are simultaneously or substantially simultaneously brought into contact with each other. The present invention is not limited thereto, and the first substrate W1 and the second substrate W2 may be bonded by boundary moving bonding that widens a region where the bonding surface WA1 of the first substrate W1 and the bonding surface WA2 of the second substrate W2 are bonded.

The boundary moving bonding is bonding that moves a boundary between a contact region in the bonding surface WA1 of the first substrate W1 in contact with the bonding surface WA2 of the second substrate W2 and a non-contact region in the bonding surface WA1 of the first substrate W1 away from the bonding surface WA2 of the second substrate W2 in the bonding surface WA1 of the first substrate W1 until the entire bonding surface WA1 of the first substrate W1 and the entire bonding surface WA2 of the second substrate W2 are in contact with each other.

In the boundary movement bonding, the first substrate W1 and the second substrate W2 are changed from the alignment completion state to the bonding completion state through the bonding start state and the bonding expansion state. Even when the first substrate W1 and the second substrate W2 are bonded by entire surface simultaneous bonding, strictly speaking, there are periods of the bonding start state and the bonding expansion state, but since the same periods are extremely short, the first substrate W1 and the second substrate W2 can be regarded as changing from the alignment completion state to the bonding completion state without passing through the bonding start state and the bonding expansion state.

Both the bonding start state and the bonding expansion state are states in the middle of the transition of the first substrate W1 and the second substrate W2 from the alignment completion state to the bonding completion state. The bonding start state is a state in which contact between the bonding surface WA1 of the first substrate W1 and the bonding surface WA2 of the second substrate W2 is started. The bonding expansion state is a state in which a region where the bonding surface WA1 of the first substrate W1 and the bonding surface WA2 of the second substrate W2 are in contact with each other is expanded until the entire region of the bonding surface WA1 of the first substrate W1 and the entire region of the bonding surface WA2 of the second substrate W2 are in contact with each other. In both the bonding start state and the bonding expansion state, a portion of the bonding surface WA1 of the first substrate W1 and a portion of the bonding surface WA2 of the second substrate W2 are in contact with each other, and the remaining portion of the bonding surface WAI of the first substrate W1 and the remaining portion of the bonding surface WA2 of the second substrate W2 are separated from each other.

The alignment completion state, the bonding start state, the bonding expansion state, and the bonding completion state are different from each other in at least one of the position of the first substrate W1 in the vertical direction with respect to the second substrate W2, the position of the first substrate W1 in the horizontal direction with respect to the second substrate W2, the posture of the first substrate W1 with respect to the second substrate W2, the relative angle between the first substrate W1 and the second substrate W2 around the vertical straight line, the shape of the bonding surface WA1 of the first substrate W1, and the shape of the bonding surface WA2 of the second substrate W2.

In addition to at least one of the bonding start state, the bonding expansion state, and the bonding completion state, the areas of the regions where the bonding surface WA1 of the first substrate W1 and the bonding surface WA2 of the second substrate W2 are in contact with each other are different from each other. The bonding expansion state represents all continuous states until the first substrate W1 and the second substrate W2 change from the bonding start state to the bonding completion state. In a process in which the first substrate W1 and the second substrate W2 change from the bonding start state to the bonding completion state through the bonding expansion state, the entire area of the bonding surface WA1 of the first substrate W1 and the entire area of the bonding surface WA2 of the second substrate W2 are bonded in a state in which the first substrate W1 and the second substrate W2 are aligned.

For example, as shown in FIG. 32A, the alignment completion state may be a state in which the entire area of the bonding surface WA1 of the first substrate W1 is arranged in one plane inclined with respect to the horizontal plane, and the entire area of the bonding surface WA2 of the second substrate W2 is arranged in one horizontal plane. Specifically, the reverse actuator 16 may adjust the angle of the first stage 13 such that the downward bonding surface WA1 of the first substrate W1 is inclined with respect to the horizontal plane. In this case, after the alignment adjustment of the first substrate W1 and the second substrate W2 is performed in a state where the bonding surface WA1 of the first substrate W1 is horizontal, the bonding surface WA1 of the first substrate W1 may be inclined, and the relative position between the first substrate W1 and the second substrate W2 in the horizontal direction may be adjusted according to the inclination angle of the bonding surface WA1 of the first substrate W1 with respect to the horizontal plane.

When the downward bonding surface WAI of the first substrate W1 is inclined with respect to the horizontal plane, a portion of the outer periphery of the bonding surface WA1 of the first substrate W1 corresponds to the lower end of the first substrate W1 disposed below the other portion of the bonding surface WA1 of the first substrate W1. The lower end of the first substrate W1 corresponds to a bonding start position at which the lower end of the first substrate W1 first comes into contact with the bonding surface WA2 of the second substrate W2. When the first substrate W1 and the second substrate W2 are changed from the alignment completion state to the bonding start state, the lower end of the first substrate W1 is brought into contact with the bonding surface WA2 of the second substrate W2 as shown in FIG. 32B. Thereafter, the first substrate W1 and the second substrate W2 are relatively moved in the Z direction and the X direction while rotating the first substrate W1 around the reversing center 16c such that the first substrate W1 rotates with respect to the second substrate W2 around a horizontal straight line that is parallel to the reversing center 16c of the first chuck 11 and passes through the lower end of the first substrate W1.

The area of the region where the bonding surface WA1 of the first substrate W1 and the bonding surface WA2 of the second substrate W2 are in contact with each other continuously increases as the inclination angle of the bonding surface WA1 of the first substrate W1 with respect to the horizontal plane decreases. When the bonding surface WA1 of the first substrate W1 becomes horizontal, the entire region of the bonding surface WA1 of the first substrate W1 and the entire region of the bonding surface WA2 of the second substrate W2 come into contact with each other. Thereby, the first substrate W1 and the second substrate W2 change from the bonding start state to the bonding completion state through the bonding expansion state. When the first substrate W1 and the second substrate W2 are bonded in this manner, bubbles (also referred to as voids) remaining between the bonded first substrate W1 and second substrate W2 can be eliminated or reduced.

The first chuck 11 releases the holding of the first substrate W1 after the first substrate W1 and the second substrate W2 are changed to the bonding completion state. The present invention is not limited thereto when the first chuck 11 includes a plurality of suction regions that generate the suction force independently of each other. The controller 3 may reduce the number of suction regions that generate the suction force as the area of the contact region increases such that the holding of the first substrate W1 is released in the contact region where the bonding surface WA1 of the first substrate W1 and the bonding surface WA2 of the second substrate W2 are in contact with each other.

Specifically, when the plurality of suction regions are arranged and shaped as shown in FIG. 10B, the controller 3 may stop the generation of the suction force in the suction regions one by one from the suction region at the right end of FIG. 10B to the suction region at the left end of FIG. 10B. In this way, the boundary extending in the vertical direction in FIG. 10B is formed between the suction region generating the suction force and the suction region not generating the suction force, and this boundary moves from the right end of the first suction surface 11s to the left end of the first suction surface 11s. Thereby, the decrease in the region where the first chuck 11 and the first substrate W1 are in contact with each other can be synchronized with the increase in the region where the first substrate W1 and the second substrate W2 are in contact with each other.

The alignment completion state may be a state in which the bonding surface WAL of the first substrate W1 is elastically deformed into a shape such as a downward convex spherical crown, and the entire region of the bonding surface WA2 of the second substrate W2 is arranged in one horizontal plane. In this case, the alignment completion state may be a state in which the positional deviation between the first substrate W1 and the second substrate W2 is minimized when the entire bonding surface WA1 of the first substrate W1 returns to a plane.

Specifically, when the bonding surface WA1 of the first substrate W1 is elastically deformed and the shape of the bonding surface WAL of the first substrate W1 in the alignment completion state can be estimated, the position of the first substrate W1 in the alignment completion state may be corrected according to the estimated shape. Regardless of whether the shape of the bonding surface WA1 of the first substrate W1 in the alignment completion state can be estimated, the shape of the bonding surface WA1 of the first substrate W1 in the alignment completion state may be measured, and the position of the first substrate W1 in the alignment completion state may be corrected according to the measured shape. For example, distances in the vertical direction from one horizontal plane to a plurality of positions in the bonding surface WA1 of the first substrate W1 may be measured using a distance meter such as a laser distance meter, and the position of the first substrate W1 in the alignment completion state may be corrected according to a value obtained by the measurement.

When the first substrate W1 and the second substrate W2 are changed from the alignment completion state to the bonding start state, the lowermost portion of the bonding surface WA1 of the first substrate W1 is brought into contact with the bonding surface WA2 of the second substrate W2. Thereafter, the distance between the first substrate W1 and the second substrate W2 is reduced while changing at least one of the position of the first substrate W1 in the horizontal direction with respect to the second substrate W2, the posture of the first substrate W1 with respect to the second substrate W2, the relative angle between the first substrate W1 and the second substrate W2 around the vertical straight line, the shape of the bonding surface WA1 of the first substrate W1, and the shape of the bonding surface WA2 of the second substrate W2. Thereby, the entire area of the bonding surface WA1 of the first substrate W1 and the entire area of the bonding surface WA2 of the second substrate W2 come into contact with each other, and the first substrate W1 and the second substrate W2 change from the bonding start state to the bonding completion state through the bonding expansion state.

Next, the advantages according to the embodiment will be described.

In the present embodiment, the bonding unit 2b the substrate bonding apparatus 1 not only bonds the first substrate W1 and the second substrate W2, but also inspects the bonding accuracy of the bonded first substrate W1 and second substrate W2. Therefore, it is not necessary to move the first substrate W1 and the second substrate W2 from the bonding unit 2b before inspecting the bonding accuracy of the first substrate W1 and the second substrate W2. Thereby, the transfer time of the first substrate W1 and the second substrate W2 can be shortened.

In the present embodiment, the second substrate W2 is held by the second chuck 21 before being bonded to the first substrate W1, and is held by the second chuck 21 even when the bonded first substrate W1 and second substrate W2 are photographed by the inspection camera 43. Therefore, it is not necessary to move the second substrate W2 from the second chuck 21 before inspecting the bonding accuracy of the first substrate W1 and the second substrate W2. Thereby, the transfer time of the first substrate W1 and the second substrate W2 can be shortened.

In the present embodiment, the bonding unit 2b is disposed in an outer wall 1a of the substrate bonding apparatus 1, and the first chuck 11, the second chuck 21, and the inspection camera 43 are disposed in the chamber 9 of the bonding unit 2b. Therefore, it is not necessary to move the first substrate W1 and the second substrate W2 to the outside of the chamber 9 before inspecting the bonding accuracy of the first substrate W1 and the second substrate W2. Thereby, the transfer time of the first substrate W1 and the second substrate W2 can be shortened.

In the present embodiment, the first chuck 11, the second chuck 21, and the inspection camera 43 are disposed above the base 20 of the bonding unit 2b, and overlap the base 20 in a plan view. In other words, the first chuck 11, the second chuck 21, and the inspection camera 43 are disposed directly above the base 20. Before the bonding accuracy of the first substrate W1 and the second substrate W2 is inspected, the first substrate W1 and the second substrate W2 may not be moved from the space immediately above the base 20. Thereby, the transfer time of the first substrate W1 and the second substrate W2 can be shortened.

In the present embodiment, the relative displacement between the base 20 and the second chuck 21 is detected not by a laser interferometer but by the displacement detector 46 of the lattice interference type. Compared to an interferometer such as a laser interferometer, the displacement detector 46 of the lattice interference type is hardly affected by a change in environment such as a change in temperature or a change in humidity, and can stably detect displacement. Further, the displacement detector 46 detects not only the relative displacement between the base 20 and the second chuck 21 in the Y direction but also the relative displacement between the base 20 and the second chuck 21 in the X direction. Therefore, the relative displacement between the base 20 and the second chuck 21 can be detected with higher accuracy as compared with the case where the detector for the Y direction and the detector for the X direction are provided.

In the present embodiment, the displacement detector 46 detects the displacement of the second chuck 21 in the X direction and the Y direction. Also, the first chuck 11 is supported by a first frame 19 fixed to the base 20. When the operation of the reverse actuator 16 is stopped, the first chuck 11 can be held in a state where the positions of the first chuck 11 in the X direction and the Y direction are fixed. Therefore, even if displacement of the first chuck 11 in the X direction and the Y direction is not detected, relative positions of the first chuck 11 and the second chuck 21 in the X direction and the Y direction can be adjusted.

In the present embodiment, the displacement of the scale 47 moving in the X direction and the Y direction together with the second chuck 21 is detected by the detection head 48. Thereby, the displacement of the second chuck 21 can be detected. Furthermore, since the detection head 48 is not in contact with the scale 47, the number of particles can be reduced as compared with a case where the detection head is in contact with the scale. In addition, since the scale 47 is moved together with the second chuck 21 instead of the detection head 48, complication of the structure can be prevented or reduced as compared with the case where the detection head 48 is moved together with the second chuck 21.

In the present embodiment, the scale 47 overlaps the second chuck 21 in a plan view. Therefore, the footprint (area of the object when viewed from directly above) of the second chuck 21 and the scale 47 can be reduced. Further, the detection head 48 overlaps the scale 47 in a plan view. Therefore, the footprint of the second chuck 21, the scale 47, and the detection head 48 can be reduced. Thereby, the substrate bonding apparatus 1 can be downsized.

In the present embodiment, the power of the two Z actuators 18 is transmitted to the first chuck 11 via the two driven bodies. The two ball nuts 18n are examples of two driven bodies. The two driven bodies correspond to the two Z actuators 18 on a one-to-one basis, and move in the Z direction together with the first chuck 11 along two straight lines parallel and vertical to each other. The two driven bodies are movable in the Z direction independently of each other. By adjusting the positions of the two driven bodies in the Z direction by the two Z actuators 18, the posture of the first substrate W1 held by the first chuck 11 can be controlled. Thereby, the posture of the first substrate W1 can be stabilized.

In the present embodiment, the reverse actuator 16 reverses the first substrate W1 held by the first chuck 11. Therefore, the first substrate W1 is held by the first chuck 11 before being reversed, and is also held by the first chuck 11 when bonded to the second substrate W2. Therefore, the first substrate W1 may not be moved from the first chuck 11 until the first substrate W1 is bonded to the second substrate W2 after being reversed. Further, the two Z actuators 18 move not only the two driven bodies and the first chuck 11 but also the reverse actuator 16 in the Z direction. Therefore, the posture of the reversed first substrate W1 can be adjusted.

In the present embodiment, the two driven bodies move in the Z direction together with the first chuck 11 along two straight lines parallel and vertical to each other. The reverse actuator 16 rotates the first substrate W1 around a horizontal straight line passing through these two straight lines. The two Z actuators 18 incline the center line 11c of the first chuck 11 in the Y direction. The reverse actuator 16 inclines the center line 11c of the first chuck 11 in the X direction. Therefore, the posture of the first substrate W1 can be more flexibly adjusted.

In the present embodiment, the first chuck 11 is guided in the Z direction by at least one linear guide 17. Thereby, the mechanical play of the mechanism that supports the first chuck 11 can be reduced, and the posture of the first substrate W1 can be further stabilized.

In the present embodiment, the first chuck 11 and the second chuck 21 are relatively moved while causing the alignment camera 45 to photograph the first fixed reference 31r and the second fixed reference 32r. The first fixed reference 31r does not overlap the first substrate W1 held by the first chuck 11, and the second fixed reference 32r does not overlap the second substrate W2 held by the second chuck 21. The first display plate 31d of the first fixed reference 31r is a transparent plate that transmits visible light. Therefore, the alignment camera 45, which is a visible light camera, can photograph the first reference mark 31m and the second reference mark 32m by photographing the second fixed reference 32r via the first fixed reference 31r.

The first reference mark 31m is an indirect reference when aligning the first substrate W1 held by the first chuck 11. Similarly, the second reference mark 32m is an indirect reference to align the second substrate W2 held by the second chuck 21. The first reference mark 31m moves together with the first substrate W1, and the second reference mark 32m moves together with the second substrate W2. Therefore, the relative position between the first substrate W1 and the second substrate W2 can be adjusted by adjusting the relative position between the first reference mark 31m and the second reference mark 32m. Thereby, alignment adjustment of the first substrate W1 and the second substrate W2 can be performed without photographing the first substrate W1 and the second substrate W2 overlapping each other.

In the present embodiment, not only the first reference mark 31m but also the first alignment mark AM1 of the first substrate W1 held by the first chuck 11 is photographed by the first camera 41. Similarly, the second camera 42 photographs not only the second reference mark 32m but also the second alignment mark AM2 of the second substrate W2 held by the second chuck 21. The relative position and angle between the first alignment mark AM1 and the first reference mark 31m can be grasped from the image photographed by the first camera 41. Similarly, the relative position and angle between the second alignment mark AM2 and the second reference mark 32m can be grasped from the image photographed by the second camera 42. Thereby, alignment adjustment of the first substrate W1 and the second substrate W2 can be performed using the first reference mark 31m and the second reference mark 32m.

In the present embodiment, the bonding surface WA1 of the first substrate W1 is inclined with respect to the bonding surface WA2 of the second substrate W2 in a state where each of the first substrate W1 and the second substrate W2 is flat. In this state, the bonding surface WA1 of the first substrate W1 is partially brought into contact with the bonding surface WA2 of the second substrate W2. Subsequently, by decreasing the inclination angle of the bonding surface WA1 of the first substrate W1 with respect to the bonding surface WA2 of the second substrate W2, the area of the region where the bonding surface WA1 of the first substrate W1 and the bonding surface WA2 of the second substrate W2 are in contact with each other is increased. In this process, the air is discharged from between the bonding surface WA1 of the first substrate W1 and the bonding surface WA2 of the second substrate W2. Thereby, bubbles remaining between the two bonded substrates W can be eliminated or reduced. Furthermore, since the first substrate W1 and the second substrate W2 are bonded in a state where each of the first substrate W1 and the second substrate W2 is flat, a structure and a mechanism to deform at least one of the first substrate W1 and the second substrate W2 are unnecessary.

In the present embodiment, alignment adjustment of the first substrate W1 and the second substrate W2 is performed in a state where the entire bonding surface WA1 of the first substrate W1 held by the first chuck 11 is parallel to the entire bonding surface WA2 of the second substrate W2 held by the second chuck 21. Therefore, the relative position and angle between the first substrate W1 and the second substrate W2 can be adjusted more precisely than in a case where alignment adjustment is performed in a state where the first substrate W1 and the second substrate W2 are not parallel. After the alignment adjustment is performed, the first substrate W1 and the second substrate W2 are bonded in the same manner as described above. Therefore, the first substrate W1 and the second substrate W2 can be bonded with higher bonding accuracy while eliminating or reducing bubbles remaining between the two bonded substrates W.

In the present embodiment, the first alignment mark AM1 of the first substrate W1 is photographed by the first camera 41. When the first alignment mark AM1 of the first substrate W1 has a shape that can specify the height direction and the width direction orthogonal to each other, it is determined whether or not an inclination angle of the first alignment mark AM1 with respect to the longitudinal direction or the horizontal direction of the image generated by the first camera 41 exceeds a first upper limit value (for example, a value greater than 0 and less than or equal to 5). When it is determined that the inclination angle of the first alignment mark AM1 exceeds the first upper limit value, the first substrate W1 and the first chuck 11 are rotated by the first rotation motor 12 such that the inclination angle of the first alignment mark AM1 decreases to the first upper limit value or less. In this way, the shape of the first alignment mark AM1 can be specified with higher accuracy from the image generated by the first camera 41, and the position and angle of the first substrate W1 can be specified with higher accuracy. Therefore, alignment adjustment of the two substrates W can be performed with higher accuracy.

In the present embodiment, the first alignment mark AM1 of the first substrate W1 is photographed by the first camera 41, and the second alignment mark AM2 of the second substrate W2 is photographed by the second camera 42. The controller 3 receives the electronic data of the photographed image, and performs the analysis of the image and the judgment based on the program stored in the memory 3c. When the second alignment mark AM2 of the second substrate W2 has a shape that can specify the height direction and the width direction orthogonal to each other, the controller 3 determines whether or not the inclination angle of the second alignment mark AM2 with respect to the longitudinal direction or the horizontal direction of the image generated by the second camera 42 exceeds the second upper limit value (for example, a value greater than 0 and less than or equal to 5). When the controller 3 determines that the inclination angle of the second alignment mark AM2 exceeds the second upper limit value, the controller 3 causes the second rotation motor 22 to rotate the second substrate W2 and the second chuck 21 such that the inclination angle of the second alignment mark AM2 decreases to the second upper limit value or less. In this way, not only the position and angle of the first substrate W1 but also the position and angle of the second substrate W2 can be specified with higher accuracy.

In the present embodiment, the reverse actuator 16 reverses the first substrate W1 held by the first chuck 11. Furthermore, at least one Z actuator 18 relatively moves the first chuck 11 and the second chuck 21 in the Z direction, thereby bonding the first substrate W1 held by the first chuck 11 and the second substrate W2 held by the second chuck 21. The first substrate W1 is held by the first chuck 11 before being reversed, and is also held by the first chuck 11 when bonded to the second substrate W2. Therefore, the first substrate W1 may not be moved from the first chuck 11 until the first substrate W1 is bonded to the second substrate W2 after being reversed. Thereby, the transfer time of the first substrate W1 and the second substrate W2 can be shortened.

In the present embodiment, a horizontal actuator such as the X actuator 27 and the Y actuator 25 moves the second chuck 21 horizontally with respect to the first chuck 11. The horizontal actuator horizontally moves not only the second chuck 21 but also the first camera 41. The first camera 41 photographs the first substrate W1 that is held by the first chuck 11 and is reversed. The horizontal actuator also serves as a photographing position adjustment actuator that changes the position photographed by the first camera 41. Therefore, the number of components of the substrate bonding apparatus 1 can be reduced as compared with a case where a photographing position adjustment actuator different from the horizontal actuator is provided.

In the present embodiment, after the first substrate W1 held by the first chuck 11 and the second substrate W2 held by the second chuck 21 are bonded, the first substrate W1 and the second substrate W2 are held by the second chuck 21, and the first substrate W1 and the second substrate W2 held by the second chuck 21 are photographed by the inspection camera 43. During this photographing, the second first substrate W1 is transferred to the first chuck 11 by the transfer robot TR. Therefore, the plurality of pairs of the first substrate W1 and the second substrate W2 can be bonded in a short time as compared with the case where the second first substrate W1 is transferred to the first chuck 11 after the bonded first substrate W1 and the second substrate W2 are carried out from the second chuck 21.

In the present embodiment, not only the second first substrate W1 is transferred to the first chuck 11 when the inspection camera 43 is photographing the first substrate W1 and the second substrate W2, but also the second first substrate W1 held by the first chuck 11 is reversed when the inspection camera 43 is photographing the first substrate W1 and the second substrate W2. Therefore, the plurality of pairs of the first substrate W1 and the second substrate W2 can be bonded in a short time as compared with a case where the second first substrate W1 is reversed after the inspection camera 43 finishes photographing.

In the present embodiment, a horizontal actuator such as the X actuator 27 or the Y actuator 25 moves the second chuck 21 horizontally with respect to the first chuck 11 between the bonding position and the photographing position. The bonding position is a position where the first substrate W1 held by the first chuck 11 and the second substrate W2 held by the second chuck 21 are bonded. The photographing position is a position where the inspection camera 43 photographs the first substrate W1 and the second substrate W2 held by the second chuck 21. The horizontal actuator also serves as a photographing position adjustment actuator that changes the position to be photographed by the inspection camera 43. Therefore, the number of components of the substrate bonding apparatus 1 can be reduced as compared with a case where a photographing position adjustment actuator different from the horizontal actuator is provided.

Next, other embodiments will be described.

The first substrate W1 may be a lower substrate W instead of the upper substrate W. That is, the upper substrate W may be the second substrate W2, and the lower substrate W may be the first substrate W1.

The inspection camera 43 may be fixed to the second frame 28 through a bracket different from the bracket 44 holding the second narrow view camera 42n and the second wide view camera 42w. The inspection camera 43 may be fixed to the base 20 through a member other than the second frame 28, such as the first frame 19. For example, the inspection camera 43 may be fixed to the first stage 13. In this case, as compared with the case where the inspection camera 43 is fixed to the second frame 28, the moving distance of the first substrate W1 and the second substrate W2 can be shortened when the first substrate W1 and the second substrate W2 are arranged in the range where the inspection camera 43 can photograph.

The first camera 41 may not photograph the first fixed reference 31r every time the first substrate W1 held by the first chuck 11 is photographed. For example, the position and angle of the first substrate W1 with respect to the first fixed reference 31r may be grasped using an image of the first fixed reference 31r photographed in advance. However, since the conditions (temperature, humidity, and the like) when the first fixed reference 31r is photographed can be different from the conditions when the first substrate W1 is photographed, in a case where the position and angle of the first substrate W1 with respect to the first fixed reference 31r are detected more precisely, it is preferable to photograph the first fixed reference 31r every time the first substrate W1 held by the first chuck 11 is photographed. The same applies to the photographing of the second fixed reference 32r.

When the first alignment mark AM1 is photographed before the first substrate W1 is held by the first chuck 11, the first alignment mark AM1 may not be photographed while the first substrate W1 is held by the first chuck 11. That is, when the first substrate W1 is held by the first chuck 11 in a state where the position and angle of the first substrate W1 are grasped in advance, the first alignment mark AM1 may not be photographed. In this case, the first camera 41 may be omitted from the bonding unit 2b. The same applies to the second camera 42.

The actuator mechanism AC may further include one or more piezo actuators that are provided on the first stage 13 and move the first chuck 11 in the Z direction. In this case, the controller 3 may lower the first substrate W1 by the Z actuator 18 and hold the first substrate W1 in a state where the bonding surface WA1 of the first substrate W1 facing downward maintains a minute interval with the bonding surface WA2 of the second substrate W2 facing upward. Thereafter, the controller 3 may bring the bonding surface WA1 of the first substrate W1 into contact with the bonding surface WA2 of the second substrate W2 facing upward by driving one or a plurality of piezo actuators.

The substrate bonding apparatus 1 is not restricted apparatus to bond two disc-shaped substrates W, and may be an apparatus to bond two polygonal substrates W.

Two or more arrangements among all the arrangements described above may be combined. Two or more steps among all the steps described above may be combined.

The base 20 is an example of a base member having a principal surface extending along a horizontal direction. The first frame 19 is an example of a supporting portion that is fixed to the base member and supports the first chuck 11. The first camera 41 is an example of a first imaging portion that moves in the X direction and the Y direction together with the second chuck 21 and images the first substrate W1. The second camera 42 is an example of a second imaging portion that is fixed in the horizontal direction and images the second substrate W2. The pair of support bases 15 is an example of a first connecting portion and a second connecting portion provided to sandwich the first substrate W1 in the Y direction perpendicular to the Z direction.

The embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

### REFERENCE SIGNS LIST

1: Substrate bonding apparatus, la: Outer wall, 2: Processing unit, 2b: Bonding unit, 2b1: First bonding module, 2b2: Second bonding module, 2c: Cleaning unit, 2h: Hydrophilizing unit, 3: Controller, 3a: Computer main body, 3b: CPU, 3c: Memory, 3d: Peripheral device, 3e: Storage, 3f: Reader, 3g: Communication device, 9: Chamber, 9p: Partition wall, 9s: Shutter, 10: Vibration removal board, 11: First chuck, 11c: Center line, 11p: Suction port, 11s: First suction surface, 11v: Valve, 12: First rotation motor, 13: First stage, 13h: Through hole, 14: Support shaft, 15: Support base, 16: Reversing center, 16c: Reverse actuator, 17: Linear guide, 17L: Rail, 17b: Slide block, 18: Z actuator, 18c: Center line, 18n: Ball nut, 18s: Ball screw, 19: First frame, 19s: First side frame, 19u: First upper frame, 20: Base, 21: Second chuck, 21c: Center line, 21s: Second suction surface, 22: Second rotation motor, 23: Second stage, 23L: Lower stage, 23u: Upper stage, 23w: Through window, 24: Linear guide, 24L: Rail, 24b: slide block, 25: Y actuator, 25f: Fixed magnet, 25m: Movable magnet, 26: Linear guide, 26L: Rail, 26b: Slide block, 27: X actuator, 27f: Fixed magnet, 27m: Movable magnet, 28: Second frame, 28s: Second side frame, 28u: Second upper frame, 31L: First fixed line, 31b: First support block, 31d: First display plate, 31m: First reference mark, 31p: First fixed point, 32L: Second fixed line, 32b: Second support block, 32d: Second display plate, 32m: Second reference mark, 32p: Second fixed point, 41: First camera, 41n: First narrow view camera, 41w: First wide view camera, 42: Second camera, 42n: Second narrow view camera, 42w: Second wide view camera, 43: Inspection camera, 44: Bracket, 44h: Through hole, 45: Alignment camera, 46: displacement detector, 47: Scale, 47s: Reflective surface, 48: Detection head, 48e: Light emitting portion, 48i: Interpolator, 48m: Main body, 48r: Light receiving element, 48s: Light source, 48x: X detection head, 48y: Y detection head, AC: Actuator mechanism, AG1: Center of gravity, AG2: Center of gravity, AH1: Horizontal axis, AH2: Horizontal axis, AM1: First alignment mark, AM2: Second alignment mark, AP1: Reference point, AP2: Reference point, AV1: Vertical axis, AV2: Vertical axis, CA: Carrier, LP: Load port, LP1: First load port, LP2: Second load port, LP3: Third load port, P: Program, RM: Removable medium, S1 to S8: Step, TH: Hand, TP: Transfer path, TR: Transfer robot, TS: Transfer system, W: Substrate, W1: First substrate, W2: Second substrate, WA1: Bonding surface, WA2: Bonding surface, WB1: Bonding layer, WB2: Bonding layer, WC1: Device layer, WC2: Device layer, WD1: Base material, WD2: Base material

1. A substrate bonding apparatus comprising:
a first chuck that holds a first substrate;
a second chuck that holds a second substrate;
a first camera that photographs a first alignment mark of the first substrate held by the first chuck;
an actuator mechanism that relatively moves the first chuck and the second chuck while the first substrate is held by the first chuck and the second substrate is held by the second chuck; and
a controller that performs alignment adjustment between the first substrate held by the first chuck and the second substrate held by the second chuck by relatively moving the first chuck and the second chuck by the actuator mechanism based on an image of the first alignment mark generated by the first camera, and then bonds the first substrate held by the first chuck and the second substrate held by the second chuck by relatively moving the first chuck and the second chuck by the actuator mechanism,
wherein the actuator mechanism includes a first rotation motor that rotates the first substrate and the first chuck around a center line of the first chuck while the first substrate is held by the first chuck, and
when the first alignment mark has a shape capable of specifying a height direction and a width direction orthogonal to each other, the controller determines whether or not an inclination angle of the first alignment mark with respect to a longitudinal direction or a lateral direction of an image generated by the first camera exceeds a first upper limit value, and when it is determined that the inclination angle of the first alignment mark exceeds the first upper limit value, the controller causes the first rotation motor to rotate the first substrate and the first chuck such that the inclination angle of the first alignment mark decreases to the first upper limit value or less, and then causes the first camera to photograph the first alignment mark.

2. The substrate bonding apparatus according to claim 1, further comprising:
a second camera that photographs a second alignment mark of the second substrate held by the second chuck,
wherein the controller performs the alignment adjustment by relatively moving the first chuck and the second chuck by the actuator mechanism based on the image of the first alignment mark generated by the first camera and the image of the second alignment mark generated by the second camera,
the actuator mechanism further includes a second rotation motor that rotates the second substrate and the second chuck around a center line of the second chuck while the second substrate is held by the second chuck, and
when the second alignment mark has a shape capable of specifying a height direction and a width direction orthogonal to each other, the controller determines whether or not an inclination angle of the second alignment mark with respect to a longitudinal direction or a lateral direction of an image generated by the second camera exceeds a second upper limit value, and when it is determined that the inclination angle of the second alignment mark exceeds the second upper limit value, the controller causes the second rotation motor to rotate the second substrate and the second chuck such that the inclination angle of the second alignment mark decreases to the second upper limit value or less, and then causes the second camera to photograph the second alignment mark.

3. (canceled)

4. A substrate bonding apparatus comprising:
a first chuck that holds a first substrate;
a second chuck that holds a second substrate;
an actuator mechanism that bonds the first substrate held by the first chuck and the second substrate held by the second chuck by relatively moving the first chuck and the second chuck;
a first fixing reference that includes a first reference mark serving as an indirect reference when aligning the first substrate held by the first chuck and a transparent first display plate on which the first reference mark is marked and that transmits visible light, the first fixing reference being provided at a position not overlapping the first substrate held by the first chuck when viewed in a direction along a center line of the first chuck, the first fixing reference moving together with the first chuck;
a second fixing reference that includes a second reference mark serving as an indirect reference when aligning the second substrate held by the second chuck and a second display plate on which the second reference mark is marked, the second fixing reference being provided at a position not overlapping the second substrate held by the second chuck when viewed in a direction along a center line of the second chuck, the second fixing reference moving together with the second chuck;
an alignment camera that is a visible light camera to photograph the first reference mark and the second reference mark by photographing the second fixed reference through the first fixed reference; and
a controller that performs alignment adjustment between the first substrate held by the first chuck and the second substrate held by the second chuck by relatively moving the first chuck and the second chuck by the actuator mechanism while causing the alignment camera to photograph the first reference mark and the second reference mark.

5. The substrate bonding apparatus according to claim 4, further comprising:
a first camera that photographs a first alignment mark of the first substrate held by the first chuck and the first reference mark; and
a second camera that photographs a second alignment mark of the second substrate held by the second chuck and the second reference mark.

6. A substrate bonding apparatus comprising:
a first chuck that is stationary in a horizontal direction and holds a first substrate;
a second chuck that is movable in the horizontal direction and holds a second substrate;
an actuator mechanism that moves the second chuck in the horizontal direction; and
a lattice interference type displacement detector that detects displacement of the second chuck in an X direction and a Y direction which are horizontal directions orthogonal to each other.

7. The substrate bonding apparatus according to claim 6,
wherein the displacement detector includes a scale that moves in the X direction and the Y direction together with the second chuck, and a detection head that detects displacement of the scale in the X direction and the Y direction in a non-contact manner with the scale.

8. The substrate bonding apparatus according to claim 7,
wherein the scale overlaps the second chuck in a plan view of the second chuck, and
the detection head overlaps the scale in a plan view of the second chuck.

9. The substrate bonding apparatus according to claim 7, further comprising:
a base member that has a principal surface extending along the horizontal direction;
a support portion that is fixed to the base member and supports the first chuck; and
a linear guide that is fixed on the principal surface of the base member,
wherein the actuator mechanism includes a horizontal actuator that moves the second chuck along the linear guide, and
the detection head is fixed to the base member.

10. The substrate bonding apparatus according to claim further comprising:
a first imaging portion that moves in the X direction and the Y direction together with the second chuck and images the first substrate; and
a second imaging portion that is fixed in the horizontal direction and images the second substrate,
wherein alignment of the first substrate and the second substrate in the horizontal direction is performed based on a first image acquired by the first imaging portion, a second image acquired by the second imaging portion, and a value indicated by the displacement detector.
